(19) United States
(12) Patent Application Publication
(10) Pub. No.: US 2023/0366939 A1
(43) Pub. Date: Nov. 16, 2023

(54) DIAGNOSIS METHOD OF SECONDARY BATTERY, CHARGING AND DISCHARGING CONTROL METHOD, DIAGNOSIS APPARATUS, MANAGEMENT SYSTEM, AND NON-TRANSITORY STORAGE MEDIUM

(71) Applicant: KABUSHIKI KAISHA TOSHIBA, Tokyo (JP)

(72) Inventors: Wataru UNO, Yokohama (JP); Yuta KANAI, Yokohama (JP); Ryosuke YAGI, Yokohama (JP)

(73) Assignee: KABUSHIKI KAISHA TOSHIBA, Tokyo (JP)

(21) Appl. No.: 18/359,929

(22) Filed: Jul. 27, 2023

Related U.S. Application Data
(63) Continuation of application No. PCT/JP2021/043843, filed on Nov. 30, 2021.

(51) Int. Cl. G01R 31/367; H01M 10/42; G01R 31/36; G01R 31/389; G01R 31/3842

(52) U.S. Cl. CPC G01R 31/367; H01M 10/425; G01R 31/3648; G01R 31/389; G01R 31/3842; H01M 2010/4271

(57) ABSTRACT

In an embodiment, a diagnosis method of a secondary battery, which includes a first electrode including a first electrode active material that performs a two-phase coexistence reaction, and a second electrode including a second active material that performs a single-phase reaction and having a polarity opposite to a polarity of the first electrode, is provided. In the method, a relationship between an SOC of the secondary battery and at least one of a charge transfer resistance and a vertex frequency of the second electrode is acquired by calculating at least one of the charge transfer resistance and the vertex frequency of the second electrode based on a measurement result of an impedance of the secondary battery for each of a plurality of SOC values of the secondary battery.

### CROSS-REFERENCE TO RELATED APPLICATIONS

This is a Continuation Application of PCT Application No. PCT/JP2021/043843, filed Nov. 30, 2021, the entire contents of which are incorporated herein by reference.

### FIELD

Embodiments described herein relate generally to a diagnosis method of a secondary battery, a charging and discharging control method, a diagnosis apparatus, a management system, and a non-transitory storage medium.

### BACKGROUND

In recent years, a secondary battery such as a lithium ion secondary battery, a lead storage battery, or a nickel hydrogen battery has widely been used for an electronic device, a vehicle, a stationary power supply device, and the like. From the viewpoint of using such battery such as a secondary battery for a long life, the internal state of the battery is estimated and degradation of the battery and the like is diagnosed based on the estimated internal state. For example, in diagnosing degradation of the battery and the like, the capacity of a positive electrode as the capacity of a positive electrode active material in the battery, the capacity of a negative electrode as the capacity of a negative electrode active material in the battery, the resistance component of the impedance of the battery, and the like are estimated as internal state parameters representing the internal state of the battery.

In the battery such as a secondary battery, when charging and discharging are repeated, the relationship between the SOC of the battery and the charging state (stoichiometry) and electric potential of the positive electrode and the relationship between the SOC of the battery and the charging state (stoichiometry) and electric potential of the negative electrode change, as compared to those at the start of use. Especially, in a case where the degrees of degradation of the positive electrode and the negative electrode are largely different from each other, the relationship between the SOC of the battery and the charging state and electric potential of one of the positive electrode and the negative electrode largely changes from that at the start of use of the battery. Thus, from the viewpoint of preventing overcharging, overdischarging, and the like of each of the positive electrode and the negative electrode, it is required to appropriately estimate a change of the relationship between the SOC of the battery and the charging state and electric potential of each of the positive electrode and the negative electrode from the relationship at the start of use of the battery, that is, a shift of the charging state (stoichiometry) of each of the positive electrode and the negative electrode from the charging state at the start of use of the battery. Therefore, in the diagnosis of the battery, it is required to be able to appropriately estimate the relationship in real time between the charging state of the electrode and the SOC of the battery.

### BRIEF DESCRIPTION OF THE DRAWINGS

FIG. 1 is a graph showing an example of the relationship between the charging state of a battery and the electric potential of each of a positive electrode and a negative electrode in regard to the battery according an embodiment.

FIG. 2 is a graph showing an example of the relationship between the stoichiometry (charging state) of a second electrode and the charge transfer resistance of the second electrode in regard to a battery as a diagnosis target according to the embodiment.

FIG. 3 is a graph showing an example of the relationship between the stoichiometry (charging state) of a first electrode and the charge transfer resistance of the first electrode in regard to the battery as the diagnosis target according to the embodiment.

FIG. 4 is a graph showing, on a complex impedance plot, an example of the frequency characteristic of the charge transfer impedance of each of the first electrode and the second electrode in regard to the battery as the diagnosis target according to the embodiment.

FIG. 5 is a graph showing an example of the relationship between the stoichiometry (charging state) of the second electrode and the vertex frequency of the charge transfer impedance of the second electrode in regard to the battery as the diagnosis target according to the embodiment.

FIG. 6 is a graph showing an example of the relationship between the stoichiometry (charging state) of the first electrode and the vertex frequency of the charge transfer impedance of the first electrode in regard to the battery as the diagnosis target according to the embodiment.

FIG. 7 is a schematic block diagram showing a management system of a battery according to the first embodiment.

FIG. 8 is a graph showing an example of a current flowing to the battery in measurement of the impedance of the battery according to the first embodiment.

FIG. 9 is a graph showing an example, different from FIG. 8, of the current flowing to the battery in measurement of the impedance of the battery according to the first embodiment.

FIG. 10 is a graph showing an example of a time change of the voltage of the battery when measuring the frequency characteristic of the impedance of the battery for each of a plurality of SOC values according to the first embodiment.

FIG. 11 is a circuit diagram schematically showing an example of the equivalent circuit of the battery used for fitting calculation according to the first embodiment.

FIG. 12 is a graph showing an example of the relationship between the charge transfer resistance of the second electrode and the SOC of the battery, which is acquired in the first embodiment.

FIG. 13 is a graph showing the relationship between the vertex frequency of the charge transfer impedance of the second electrode and the SOC of the battery in a case where the relationship in the example shown in FIG. 12 is acquired.

FIG. 14 is a flowchart schematically illustrating an example of processing in the diagnosis of the battery, which is performed by a diagnosis apparatus according to the first embodiment.

FIG. 15 is a graph showing an example of the relationship between the charge transfer resistance of a second electrode and the SOC of a battery in each of a first time and a second time after the first time, which is acquired in the second embodiment.

FIG. 16 is a graph showing the relationship between the vertex frequency of the charge transfer impedance of the second electrode and the SOC of the battery in each of the first time and the second time after the first time, in a case where the relationship in the example shown in FIG. 15 is acquired.

FIG. 17 is a flowchart schematically illustrating an example of processing in the diagnosis of the battery, which is performed by a diagnosis apparatus according to the second embodiment.

FIG. 18 is a flowchart schematically illustrating an example of processing in the diagnosis of a battery performed by a diagnosis apparatus according to the third embodiment.

FIG. 19 is a schematic block diagram showing a management system of a battery according to the fourth embodiment.

FIG. 20 is a flowchart schematically illustrating an example of processing in the diagnosis of the battery, which is performed by a diagnosis apparatus according to the fourth embodiment.

### DETAILED DESCRIPTION

According to an embodiment, a diagnosis method of a secondary battery, which includes a first electrode including a first electrode active material that performs a two-phase coexistence reaction, and a second electrode including a second active material that performs a single-phase reaction and having a polarity opposite to a polarity of the first electrode, is provided. In the method, a relationship between an SOC of the secondary battery and at least one of a charge transfer resistance and a vertex frequency of the second electrode is acquired by calculating at least one of the charge transfer resistance and the vertex frequency of the second electrode based on a measurement result of an impedance of the secondary battery for each of a plurality of SOC values of the secondary battery.

Embodiments will be described below with reference to the accompanying drawings.

A battery as a diagnosis target in this embodiment will be described first. The battery as the diagnosis target is, for example, a secondary battery such as a lithium ion secondary battery, a lead storage battery, or a nickel hydrogen battery. The battery may be formed by a unit cell (unit battery), or may be a battery module or a cell block formed by electrically connecting a plurality of unit cells. When the battery is formed by a plurality of unit cells, the plurality of unit cells may electrically be connected in series or in parallel in the battery. In addition, both a series connection structure in which a plurality of unit cells are connected in series and a parallel connection structure in which a plurality of unit cells are connected in parallel may be formed in the battery. Furthermore, the battery may be any one of a battery string, a battery array, and a storage battery, in each of which a plurality of battery modules are electrically connected. In addition, in a battery module in which a plurality of unit cells are electrically connected, each of the plurality of unit cells may be diagnosed as a battery of a diagnosis target. Note that the secondary battery will simply be referred to as a “battery” in the following description.

In the battery as described above, the electric charge amount (charging amount) and the SOC of the battery are defined as parameters representing the charging state of the battery. If time t and an electric charge amount q of the battery are defined, an electric charge amount 1(t1) at time t=t1 is calculated by equation (1) below using an electric charge amount q(t0) at time t=t0 and a time change I(t) of a current flowing to the battery. Therefore, the electric charge amount of the battery in real time can be calculated based on the electric charge amount of the battery at a predetermined time point and a time change from the predetermined time point concerning the current flowing to the battery.

q(t1)=q(t0)+∫ₜ₀^{t1}1(t)dt (1)

In the battery, for the voltage, a lower limit voltage Vmin and an upper limit voltage Vmax are defined. In addition, an SOC value is defined as the value of an SOC of the battery. In the battery, a state in which the voltage in discharging or charging under a predetermined condition becomes the lower limit voltage Vmin is defined as a state in which the SOC value is 0 (0%), and a state in which the voltage in discharging or charging under a predetermined condition becomes the upper limit voltage Vmax is defined as a state in which the SOC value is 1 (100%). Furthermore, in the battery, a charging capacity (charging electric charge amount) until the SOC value changes from 0 to 1 in charging under a predetermined condition or a discharging capacity (discharging electric charge amount) until the SOC value changes from 1 to 0 in discharging under a predetermined condition is defined as a battery capacity. The ratio of a remaining electric charge amount (remaining capacity) until the state in which the SOC value is 0 to the battery capacity of the battery is the SOC of the battery.

Each of a positive electrode and a negative electrode as the electrodes of the battery has an electric potential corresponding to the charging state. In each of the electrodes, for example, stoichiometry is defined as a parameter representing the charging state. Each of the positive electrode and the negative electrode has a predetermined relationship between the electric potential and the charging state (stoichiometry). For this reason, for each of the electrodes of the battery, it is possible to calculate the electric potential based on the charging state (stoichiometry), and calculate the stoichiometry and the like based on the electric potential.

In the battery such as a secondary battery, when charging and discharging are repeated, the relationship between the SOC of the battery and the charging state (stoichiometry) and electric potential of each of the electrodes (the positive electrode and the negative electrode) changes, as compared to that at the start of use of the battery. Especially, in a case where the degrees of degradation of the positive electrode and the negative electrode are largely different from each other, the relationship between the SOC of the battery and the charging state and electric potential of one of the positive electrode and the negative electrode largely changes from that at the start of use of the battery. In the embodiment, for the battery as the diagnosis target, the relationship in real time between the SOC of the battery and the charging state and electric potential of each of the electrodes is estimated. Then, a change of the relationship between the SOC of the battery and the charging state and electric potential of each of the electrodes from the relationship at the start of use of the battery, that is, a shift of the charging state such as the stoichiometry of each of the positive electrode and the negative electrode from the charging state at the start of use of the battery is estimated. By appropriately estimating the relationship in real time between the SOC of the battery and the charging state and electric potential of each of the electrodes, a shift of the charging state of each of the electrodes from the charging state at the start of use of the battery, and the like, it is possible to appropriately prevent overcharging, overdischarging, and the like of each of the positive electrode and the negative electrode.

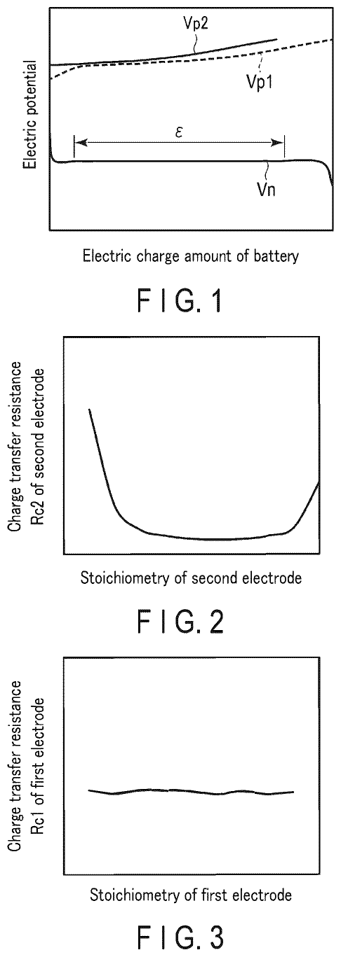

FIG. 1 is a graph showing an example of the relationship between the charging state of the battery and the electric potential of each of the positive electrode and the negative electrode in regard to the battery according an embodiment. In FIG. 1, the abscissa represents the electric charge amount (charging amount) of the battery in the charging state of the battery, and the ordinate represents the electric potential. FIG. 1 shows relationships Vp1 and Vp2 between the electric charge amount of the battery and the electric potential of the positive electrode and a relationship Vn between the electric charge amount of the battery and the electric potential of the negative electrode. In the battery in the example shown in FIG. 1, when charging and discharging are repeated, the relationship between the electric charge amount of the battery and the electric potential of the positive electrode changes from the relationship Vpl to the relationship Vp2. When compared under the condition that the electric charge amounts of the battery are identical to each other, the electric potential of the positive electrode is higher in the relationship Vp2 than in the relationship Vp1. For this reason, in the example shown in FIG. 1, if the positive electrode degrades, the electric potential of the positive electrode after the degradation is shifted to the high electric potential side with respect to the electric potential of the positive electrode before the degradation when compared under the condition that the electric charge amounts of the battery are identical to each other. Since the relationship between the electric charge amount of the battery and the electric potential of the positive electrode changes as described above, in the example shown in FIG. 1, the relationship between the SOC of the battery and the charging state and electric potential of the positive electrode changes from that at the start of use of the battery, the stoichiometry of the positive electrode is shifted with respect to that at the start of use of the battery.

In addition, in the battery as the diagnosis target, one of the positive electrode and the negative electrode is defined as a first electrode, and one of the positive electrode and the negative electrode, which has a polarity opposite to that of the first electrode, is defined as a second electrode. In the battery as the diagnosis target, the first electrode includes a first electrode active material as an electrode active material, and the second electrode includes a second electrode active material different from the first electrode active material as an electrode active material. If the SOC value of the battery changes within the range of 0 to 1 (0% to 100%), the charging state (stoichiometry) of the first electrode changes within a first range, and the charging state (stoichiometry) of the second electrode changes within a second range. If the charging state of the first electrode falls within the above-described first range, the first electrode active material performs a two-phase coexistence reaction in each of occlusion and release of lithium. If the charging state of the second electrode falls within the above-described second range, the second electrode active material performs a single-phase reaction (solid solution reaction) in each of occlusion and release of lithium. The first electrode including the first electrode active material that performs a two-phase coexistence reaction has a plateau region where the electric potential (open circuit potential) is constant or almost constant even if the stoichiometry (charging state) changes. In the example shown in FIG. 1, the negative electrode serves as the first electrode including the first electrode active material that performs a two-phase coexistence reaction, and the negative electrode has a plateau region E.

In an example, the battery as the diagnosis target is a lithium ion secondary battery that is charged and discharged as lithium ions move between the positive electrode and the negative electrode. In this case, the first electrode contains the first electrode active material that performs a two-phase coexistence reaction in each of occlusion and release of lithium, and the second electrode contains the second electrode active material that performs a single-phase reaction in each of occlusion and release of lithium. If the negative electrode serves as the first electrode, examples of the first electrode active material (negative electrode active material) that performs a two-phase coexistence reaction in the negative electrode are lithium titanate, titanium oxide, and niobium titanium oxide. In this case, in the positive electrode serving as the second electrode, a layered oxide such as lithium nickel cobalt manganese oxide, lithium cobalt oxide, or lithium nickel cobalt aluminum oxide is used as the second electrode active material (positive electrode active material) that performs a single-phase reaction. If the positive electrode serves as the first electrode, lithium iron phosphate, lithium manganese oxide, or the like is used as the first electrode active material (positive electrode active material) that performs a two-phase coexistence reaction in the positive electrode. In this case, in the negative electrode serving as the second electrode, a carbon-based active material or the like is used as the second electrode active material (negative electrode active material) that performs a single-phase reaction.

In the embodiment or the like, when the relationship in real time between the SOC of the battery and the charging state and electric potential of each of the electrodes (the first electrode and the second electrode) is estimated, the impedance of the battery as the diagnosis target and the frequency characteristic of the impedance are measured. The resistance component of the impedance of the battery is calculated based on the measurement result of the frequency characteristic of the impedance of the battery. Here, the impedance components of the battery include an ohmic resistance including a resistance in the moving process of lithium in an electrolyte or the like, the charge transfer impedance of each of the positive electrode and the negative electrode, an impedance derived from a coat, including a coat resistance of a coat formed on the positive electrode or the negative electrode by a reaction or the like, a Warburg impedance including a diffusion resistance, and the inductance component of the battery. In each of the positive electrode and the negative electrode, the resistance component of the charge transfer impedance is the charge transfer resistance. The impedance components of the battery, including the charge transfer resistances of the first electrode and the second electrode, can be calculated using the frequency characteristic of the impedance of the battery.

In the second electrode active material that performs a single-phase reaction, parameters proportional to the reciprocal of the charge transfer resistance, such as an AC charge density and a vertex frequency (to be described later) change in accordance with the charging state of the second electrode as the charging state of the second electrode changes. For example, when the abscissa represents the stoichiometry (charging state) of the second electrode and the ordinate represents the AC charge density of the second electrode active material, the relationship between the stoichiometry of the second electrode and the AC charge density of the second electrode active material is plotted. In this case, the plotted relationship between the stoichiometry of the second electrode and the AC charge density of the second electrode active material (the reciprocal of the charge transfer resistance of the second electrode active material) has a convex shape to the higher side (upper side) of the AC charge density.

FIG. 2 is a graph showing an example of the relationship between the stoichiometry (charging state) of the second electrode and the charge transfer resistance of the second electrode in regard to the battery as the diagnosis target according to the embodiment. In FIG. 2, the abscissa represents the stoichiometry of the second electrode as the charging state of the second electrode, and the ordinate represents a charge transfer resistance Rc2 of the second electrode. Since in the battery of the embodiment or the like, the relationship between the stoichiometry of the second electrode and the AC charge density of the second electrode active material is as described above, the charge transfer resistance Rc2 of the second electrode changes in accordance with the charging state of the second electrode as the charging state of the second electrode changes, as shown in FIG. 2 or the like. Then, the relationship between the stoichiometry of the second electrode and the charge transfer resistance Rc2 of the second electrode plotted in FIG. 2 or the like has a convex shape to the lower side of the charge transfer resistance.

FIG. 3 is a graph showing an example of the relationship between the stoichiometry (charging state) of the first electrode and the charge transfer resistance of the first electrode in regard to the battery as the diagnosis target according to the embodiment. In FIG. 3, the abscissa represents the stoichiometry of the first electrode as the charging state of the first electrode, and the ordinate represents a charge transfer resistance Rc1 of the first electrode. As shown in FIG. 3 or the like, in the first electrode including the first electrode active material that performs a two-phase coexistence reaction, even if the stoichiometry (charging state) changes, the charge transfer resistance Rc1 remains unchanged or almost unchanged. That is, the charge transfer resistance Rc1 of the first electrode is maintained constant or almost constant even if the stoichiometry of the first electrode changes.

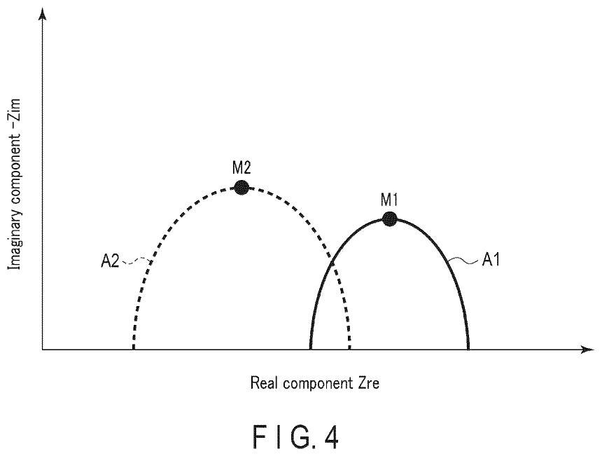

The frequency characteristic of the impedance of the battery and the frequency characteristic of the charge transfer impedance for each of the first electrode and the second electrode are shown on, for example, a Nyquist diagram such as a complex impedance plot (Cole-Cole plot). FIG. 4 is a graph showing, on a complex impedance plot, an example of the frequency characteristic of the charge transfer impedance of each of the first electrode and the second electrode in regard to the battery as the diagnosis target according to the embodiment. In FIG. 4, the abscissa represents a real component Zre of the impedance and the ordinate represents an imaginary component −Zim of the impedance. Furthermore, in FIG. 4, a solid line indicates the frequency characteristic of the charge transfer impedance of the first electrode, and a broken line indicates the frequency characteristic of the charge transfer impedance of the second electrode.

As shown in FIG. 4 or the like, in the frequency characteristic of the charge transfer impedance of each of the first electrode and the second electrode plotted on the complex impedance plot, an arc portion (a corresponding one of arc portions A1 and A2) that is convex to the negative side (upper side) of the imaginary component is shown. In an impedance locus representing the frequency characteristic of the charge transfer impedance of the first electrode, the frequency at a vertex M1 of the arc portion A1, that is, the frequency at a local minimum of the imaginary component of the impedance corresponds to a vertex frequency F1 of the charge transfer impedance of the first electrode. In an impedance locus representing the frequency characteristic of the charge transfer impedance of the second electrode, the frequency at a vertex M2 of the arc portion A2, that is, the frequency at a local minimum of the imaginary component of the impedance corresponds to a vertex frequency F2 of the charge transfer impedance of the second electrode.

In an example, using the equivalent circuit of the battery as the diagnosis target and the measurement result of the frequency characteristic of the impedance of the battery, the impedance components of the battery including the charge transfer resistances of the first electrode and the second electrode are calculated. In this case, in the equivalent circuit, as electric characteristic parameters (circuit constants) corresponding to the impedance components of the charge transfer impedance of the first electrode, a capacitance C1 and a Debye experience parameter al are set in addition to the above-described charge transfer resistance Rc1 of the first electrode. Then, in the equivalent circuit, as electric characteristic parameters corresponding to the impedance components of the charge transfer impedance of the second electrode, a capacitance C2 and a Debye experience parameter α2 are set in addition to the above-described charge transfer resistance Rc2 of the second electrode.

If the vertex frequency F1 of the charge transfer impedance of the first electrode and the vertex frequency F2 of the charge transfer impedance of the second electrode are set, a vertex frequency Fi (i=1, 2) has a relationship given by equation (2) below with respect to a charge transfer resistance Rci, a capacitance Ci and a

Debye experience parameter ai. Note that in the equivalent circuit of the battery, a CPE (Constant Phase Element) Qi is provided as a circuit element, and the capacitance Ci and the Debye experience parameter ai are electric characteristic parameters of the CPE Qi.

$$Fi = \frac{1}{2 {π ( Rci Ci )}^{1 / α i}} ( i = 1 , 2 ) \qquad ( 2 )$$

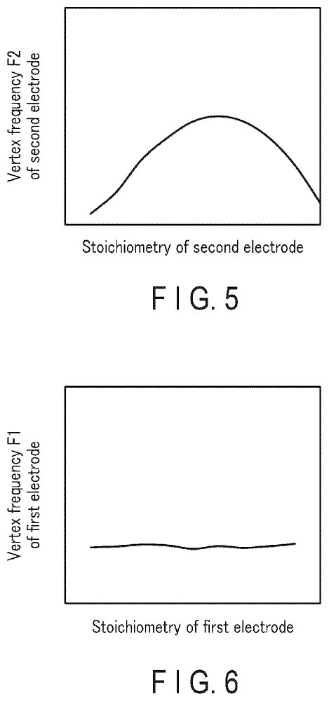

FIG. 5 is a graph showing an example of the relationship between the stoichiometry (charging state) of the second electrode and the vertex frequency of the charge transfer impedance of the second electrode in regard to the battery as the diagnosis target according to the embodiment. In FIG. 5, the abscissa represents the stoichiometry of the second electrode as the charging state of the second electrode, and the ordinate represents the vertex frequency F2 of the charge transfer impedance of the second electrode. As shown in FIG. 5 or the like, in the battery of the embodiment or the like, the vertex frequency F2 of the second electrode changes in accordance with the charging state of the second electrode. The relationship between the stoichiometry of the second electrode and the vertex frequency of the charge transfer impedance of the second electrode plotted in FIG. 5 or the like has a convex shape to the higher side (upper side) of the vertex frequency.

FIG. 6 is a graph showing an example of the relationship between the stoichiometry (charging state) of the first electrode and the vertex frequency of the charge transfer impedance of the first electrode in regard to the battery as the diagnosis target according to the embodiment. In FIG. 6, the abscissa represents the stoichiometry of the first electrode as the charging state of the first electrode, and the ordinate represents the vertex frequency F1 of the charge transfer impedance of the first electrode. As shown in FIG. 6 or the like, in the first electrode containing the first electrode active material that performs a two-phase coexistence reaction, even if the stoichiometry (charging state) changes, the vertex frequency F1 of the charge transfer impedance remains unchanged or almost unchanged. That is, the vertex frequency F1 of the first electrode is maintained constant or almost constant even if the stoichiometry of the first electrode changes.

As described above, the battery as the diagnosis target according to the embodiment or the like includes the first electrode including the first electrode active material that performs a two-phase coexistence reaction, and the second electrode including the second active material that performs a single-phase reaction and having a polarity opposite to that of the first electrode, and has the above-described characteristic. Therefore, as the SOC of the battery as the diagnosis target changes, the charge transfer resistance Rc2 and the vertex frequency F2 of the second electrode change in accordance with the SOC of the battery. On the other hand, even if the SOC of the battery as the diagnosis target changes, the charge transfer resistance Rc1 and the vertex frequency F1 of the first electrode remain unchanged or almost unchanged.

Therefore, the relationship between the SOC of the battery and the charge transfer resistance Rc1, the vertex frequency F1, and the like of the first electrode is different from the relationship between the SOC of the battery and the charge transfer resistance Rc2, the vertex frequency F2, and the like of the second electrode. In the embodiment or the like, using the above-described difference between the two relationships of the battery as the diagnosis target, the relationship between the SOC of the battery and at least one of the stoichiometry and the electric potential of each of the first electrode and the second electrode is acquired, and a change of the relationship between the SOC of the battery and at least one of the stoichiometry (charging state) and the electric potential of each of the electrodes from the relationship at the start of use of the battery is estimated. Thus, it is possible to appropriately estimate a shift of the stoichiometry of each of the first electrode and the second electrode from the stoichiometry at the start of use of the battery, and to calculate a usable stoichiometry range, a usable electric potential range, and the like in regard to each of the first electrode and the second electrode.

### First Embodiment

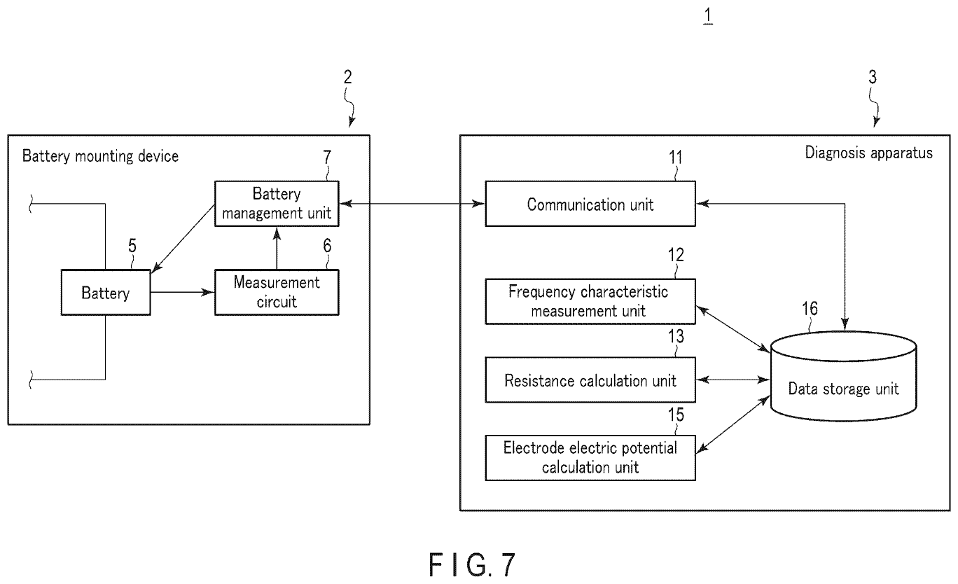

As an example of the embodiment, the first embodiment will be described first. FIG. 7 is a schematic block diagram showing a management system of a battery according to the first embodiment. As shown in FIG. 7, a management system 1 includes a battery mounting device 2 and a diagnosis apparatus 3. A battery 5, a measurement circuit 6, and a battery management unit (BMU) 7 are mounted in the battery mounting device 2. Examples of the battery mounting device 2 are a large power storage apparatus for an electric power system, a smartphone, a vehicle, a stationary power supply device, a robot, and a drone, and examples of a vehicle serving as the battery mounting device 2 are a railroad vehicle, an electric bus, an electric car, a plug-in hybrid car, and an electric motorcycle. As the battery 5, the above-described battery is used. Hence, the battery 5 includes a first electrode including a first electrode active material that performs a two-phase coexistence reaction, and a second electrode including a second electrode active material that performs a single-phase reaction and having a polarity opposite to that of the first electrode.

The measurement circuit 6 detects and measures parameters associated with the battery 5. The measurement circuit 6 periodically detects and measures the parameter at a predetermined timing. In a state in which the battery 5 is charged or discharged, the measurement circuit 6 periodically measures the parameters associated with the battery 5. Even in a state where a signal for measurement of a current or the like (to be described later) for which the impedance of the battery 5 is measured is input to the battery 5, the measurement circuit 6 periodically measures the parameters associated with the battery 5. The parameters associated with the battery 5 include a current flowing to the battery 5 and the voltage of the battery 5. Therefore, the measurement circuit 6 includes an ammeter that measures a current and a voltmeter that measures a voltage.

The battery management unit 7 forms a processing apparatus (computer) for managing the battery 5 by, for example, controlling charging and discharging of the battery 5, and includes a processor and a storage medium (non-transitory storage medium). The processor includes one of a CPU (Central Processing Unit), an ASIC (Application Specific Integrated Circuit), a microcomputer, an FPGA (Field Programmable Gate Array), and a DSP (Digital Signal Processor). The storage medium can include an auxiliary storage device in addition to a main storage device such as a memory. As the storage medium, a magnetic disk, an optical disk (a CD-ROM, a CD-R, a DVD, or the like), a magnetooptical disk (an MO or the like), a semiconductor memory, or the like can be used. The battery management unit 7 may include only one processor and one storage medium, or may include a plurality of processors and a plurality of storage media. In the battery management unit 7, the processor performs processing by executing a program and the like stored in the storage medium. The program to be executed by the processor in the battery management unit 7 may be stored in a computer (server) connected via a network such as the Internet or a server in a cloud environment. In this case, the processor downloads the program via the network.

The diagnosis apparatus 3 diagnoses degradation of the battery 5 and the like. Therefore, the battery 5 is the diagnosis target of the diagnosis apparatus 3. In an example shown in FIG. 7 or the like, the diagnosis apparatus 3 is provided outside the battery mounting device 2. The diagnosis apparatus 3 includes a communication unit 11, a frequency characteristic measurement unit 12, a resistance calculation unit 13, an electrode electric potential calculation unit 15, and a data storage unit 16. The diagnosis apparatus 3 is, for example, a server that can communicate with the battery management unit 7 via the network. In this case, similar to the battery management unit 7, the diagnosis apparatus 3 includes a processor and a storage medium. Then, the communication unit 11, the frequency characteristic measurement unit 12, the resistance calculation unit 13, and the electrode electric potential calculation unit 15 execute some of processes performed by the processor of the diagnosis apparatus 3 and the like, and the storage medium of the diagnosis apparatus 3 functions as the data storage unit 16.

Note that in an example, the diagnosis apparatus 3 may be a cloud server formed in a cloud environment. The infrastructure of the cloud environment is formed by a virtual processor such as a virtual CPU and a cloud memory. Hence, if the diagnosis apparatus 3 is a cloud server, the communication unit 11, the frequency characteristic measurement unit 12, the resistance calculation unit 13, and the electrode electric potential calculation unit 15 execute some of processes performed by the virtual processor. The cloud memory functions as the data storage unit 16.

The data storage unit 16 may be provided in a computer separated from the battery management unit 7 and the diagnosis apparatus 3. In this case, the diagnosis apparatus 3 is connected, via a network, to the computer in which the data storage unit 16 and the like are provided. Alternatively, the diagnosis apparatus 3 may be mounted in the battery mounting device 2. In this case, the diagnosis apparatus 3 is formed from a processing apparatus or the like mounted in the battery mounting device 2. If the diagnosis apparatus 3 is mounted in the battery mounting device 2, one processing apparatus or the like mounted in the battery mounting device 2 may perform processing of the battery management unit 7 such as control of charging and discharging of the battery 5 while performing processing (to be described later) of the diagnosis apparatus 3. The processing of the diagnosis apparatus 3 will be described below.

The communication unit 11 communicates with a processing apparatus other than the diagnosis apparatus 3 via the network. For example, the communication unit 11 receives, from the battery management unit 7, measurement data including the measurement results, by the measurement circuit 6, of the above-described parameters associated with the battery 5. The measurement data is generated by the battery management unit 7 and the like based on the measurement results by the measurement circuit 6. The measurement data includes the measured values of the parameters associated with the battery 5. If the parameters associated with the battery 5 are measured at each of a plurality of time points of measurement, the measurement data includes the measured values of the parameters associated with the battery 5 at each of the plurality of time points of measurement and time changes (time histories) of the parameters associated with the battery 5. Therefore, the measurement data includes the time change (time history) of the current of the battery 5 and the time change (time history) of the voltage of the battery 5. The communication unit 11 writes the received measurement data in the data storage unit 16.

At least one of the processors of the battery management unit 7 and the diagnosis apparatus 3 estimates the electric charge amount (charging amount) and the SOC of the battery 5 based on the measurement results, by the measurement circuit 6, of the parameters associated with the battery 5. Then, the diagnosis apparatus 3 acquires, as data included in the above-described measurement data, the estimated value and the time change (time history) of the estimated value in regard to each of the charging amount and the SOC of the battery 5. The charging amount of the battery 5 in real time is calculated in the above-described way. Then, the SOC of the battery 5 is defined, as described above, and the SOC of the battery 5 in real time is calculated in the above-described way.

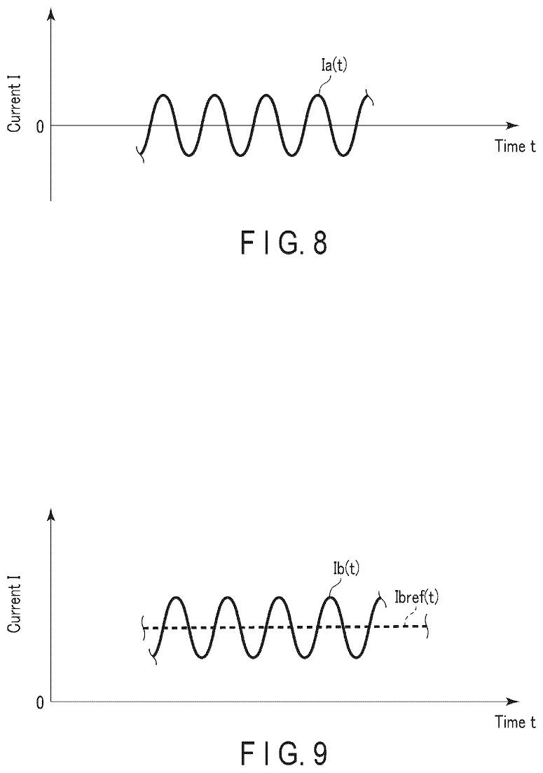

The frequency characteristic measurement unit 12 measures the impedance of the battery 5 as the determination target based on the measurement data and the like received by the communication unit 11. In measurement of the impedance of the battery 5 by the frequency characteristic measurement unit 12, the battery management unit 7 and the like cause a current with a current waveform with a periodically changing current value to flow to the battery 5. FIG. 8 is a graph showing an example of a current flowing to the battery in measurement of the impedance of the battery according to the first embodiment. FIG. 9 is a graph showing an example, different from FIG. 8, of the current flowing to the battery in measurement of the impedance of the battery according to the first embodiment. In FIGS. 8 and 9, the abscissa represents time t and the ordinate represents a current I.

In an example shown in FIG. 8, in measurement of the impedance of the battery 5, the battery management unit 7 and the like input, to the battery 5, an AC current Ia(t) with a current waveform with a periodically changing flowing direction. On the other hand, in an example shown in FIG. 9, a superimposed current Ib(t) generated by superimposing the current waveform of the AC current on a reference current locus Ibref(t) of a DC current is input to the battery 5. In the superimposed current Ib(t) input to the battery 5, the current value periodically changes with the reference current locus Ibref(t) being as the center. The superimposed current Ib(t) is a DC current whose flowing direction remains unchanged. The reference current locus Ibref(t) is, for example, the locus of the time change of a charging current set as a charging condition for charging or the like of the battery 5.

In an example, the impedance of the battery 5 is measured simultaneously with charging of the battery 5 (adjustment of the SOC of the battery 5). In this case, like the superimposed current Ib(t) in the example shown in FIG. 9, a superimposed current generated by superimposing the current waveform of the AC current on the reference current locus of a DC current set as the locus of the time change of the charging current is input to the battery 5. The superimposed current is a DC current whose current value periodically changes with the reference current locus being as the center in changing. In the reference current locus in charging, the current value of the charging current may be constant over time, or the current value of the charging current may change with time. In addition, each of the current waveform of the AC current Ia(t) shown in FIG. 8 and the current waveform of the superimposed current Ib(t) shown in FIG. 9 is a sinusoidal wave (sin wave). However, the current waveform of each of the AC current and the superimposed current may be a current waveform such as a triangular wave or a sawtooth wave other than the sinusoidal wave.

In a state in which the current with the current waveform with the periodically changing current value is input to the battery 5, as described above, the measurement circuit 6 measures the current and the voltage of the battery 5 at each of the plurality of time points of measurement. The communication unit 11 of the diagnosis apparatus 3 receives, as the above-described measurement data, the measurement results of the current and the voltage of the battery 5 obtained in the state in which the current with the current waveform with the periodically changing current value is input to the battery 5. The measurement results of the current and the voltage of the battery 5 obtained in the state in which the current with the current waveform with the periodically changing current value is caused to flow to the battery 5 include the measured values of the current and the voltage of the battery 5 at each of the plurality of time points of measurement, and the time changes (time histories) of the current and the voltage of the battery 5.

The frequency characteristic measurement unit 12 calculates the frequency characteristic of the impedance of the battery 5 based on the measurement results received by the communication unit 11. Therefore, by causing the current with the current waveform with the periodically changing current value to flow to the battery 5, the frequency characteristic of the impedance of the battery 5 is measured. In an example, the frequency characteristic measurement unit 12 calculates a peak-to-peak value (variation width) in the periodical change of the current of the battery 5 based on the time change of the current of the battery 5, and calculates a peak-to-peak value (variation width) in the periodical change of the voltage of the battery 5 based on the time change of the voltage of the battery 5. The frequency characteristic measurement unit 12 then calculates the impedance of the battery 5 from the ratio of the peak-to-peak value of the voltage to the peak-to-peak value of the current.

In measurement of the frequency characteristic of the impedance of the battery 5, the battery management unit 7 and the like change, within a predetermined frequency range, the frequency of the current waveform of the current to be input to the battery 5. Then, the communication unit 11 receives, as the measurement data, the measurement results of the current and the voltage of the battery 5 in a state in which the current is input to the battery 5 at each of a plurality of frequencies within the predetermined frequency range. The frequency characteristic measurement unit 12 calculates the impedance of the battery 5, as described above, in the state in which the current is input to the battery 5 at each of the frequencies within the predetermined frequency range based on the measurement data. Thus, the frequency characteristic measurement unit 12 measures the impedance of the battery 5 at each of the plurality (a number) of frequencies different from each other, and measures the impedance characteristic of the battery 5. For example, the impedance of the battery 5 is measured at each of the plurality of frequencies within a range of 0.01 mHz (inclusive) to 10 MHz (inclusive), thereby measuring the impedance characteristic of the battery 5.

In another example, the battery management unit 7 and the like cause the current with the current waveform of the reference frequency to flow to the battery 5, and the diagnosis apparatus 3 acquires, as the measurement data, the time changes of the current and the voltage of the battery 5. Then, the frequency characteristic measurement unit 12 calculates the frequency spectra and the like of the current and the voltage of the battery 5 as the frequency characteristics of the current and the voltage of the battery 5 by performing Fourier transform or the like for the time changes of the current and the voltage of the battery 5. In each of the calculated frequency spectra of the current and the voltage of the battery 5, components of integer multiples of the reference frequency are indicated in addition to components of the reference frequency. Then, the frequency characteristic measurement unit 12 calculates the auto-correlation function of the time change of the current of the battery 5 and the cross-correlation function between the time change of the current of the battery 5 and the time change of the voltage of the battery 5 based on the frequency characteristics of the current and the voltage of the battery 5. The frequency characteristic measurement unit 12 calculates the frequency characteristic of the impedance of the battery 5 using the auto-correlation function and the cross-correlation function. The frequency characteristic of the impedance of the battery 5 is calculated by, for example, dividing the cross-correlation function by the auto-correlation function.

The frequency characteristic measurement unit 12 acquires, for example, a complex impedance plot (Cole-Cole plot) of the impedance as the measurement result of the frequency characteristic of the impedance of the battery 5. On the complex impedance plot, the impedance of the battery 5 is plotted for each of the plurality (a number) of frequencies. Then, on the complex impedance plot, the real component and imaginary component of the impedance of the battery 5 are plotted for each of the plurality of frequencies. Note that the method of measuring the frequency characteristic of the impedance of the battery by inputting the current with the current waveform with the periodically changing current value to the battery, the complex impedance plot as the measurement result of the frequency characteristic of the impedance of the battery, and the like are described in reference literature 1 (J. P. Schmidt et al., “Studies on LiFePO4 as cathode materials using impedance spectrometry” Journal of power Sources. 196, (2011), pp. 5342-5348), and the like.

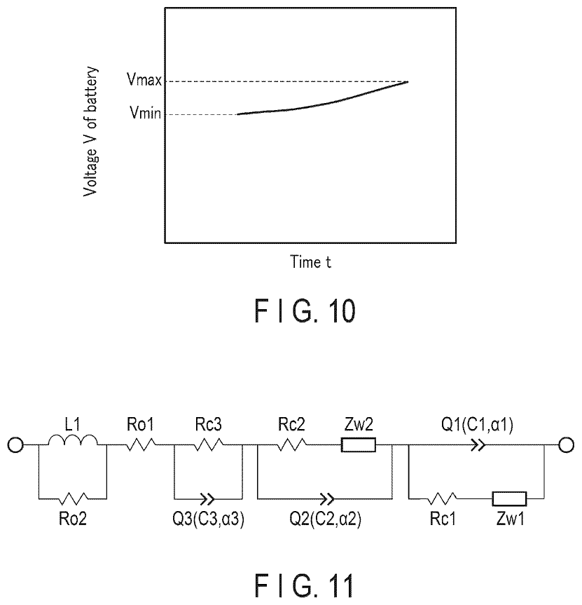

The frequency characteristic measurement unit 12 measures the frequency characteristic of the impedance of the battery 5 for each of the plurality of SOC values of the battery 5 in the above-described way. At this time, the SOC of the battery 5 is adjusted to each of the SOC values as the measurement target of the frequency characteristic of the impedance by, for example, charging the battery 5 by the battery management unit 7 and the like. FIG. 10 is a graph showing an example of a time change of the voltage of the battery when measuring the frequency characteristic of the impedance of the battery for each of the plurality of SOC values according to the first embodiment. In FIG. 10, the abscissa represents time t and the ordinate represents a voltage V of the battery 5. In an example shown in FIG. 10, after the voltage V of the battery 5 is adjusted to the lower limit voltage Vmin, that is, the SOC value of the battery 5 is adjusted to 0, the frequency characteristic of the impedance of the battery 5 in a state in which the voltage V is the lower limit voltage Vmin is measured.

Then, while charging the battery 5 from the lower limit voltage Vmin, the SOC of the battery 5 is adjusted to each of the plurality of SOC values as the measurement target of the frequency characteristic of the impedance, and the frequency characteristic of the impedance of the battery 5 is measured for each of the SOC values as the measurement target. At this time, the intervals of the plurality of SOC values of the battery 5 as the measurement targets of the frequency characteristic of the impedance may or may not be equal to each other. When the voltage V becomes the upper limit voltage Vmax, the frequency characteristic of the impedance of the battery 5 in a state in which the voltage V is the upper limit voltage Vmax (the SOC value is 1) is measured, thereby ending charging of the battery 5.

In an example, after the SOC of the battery 5 is adjusted to each of the SOC values as the measurement target by, for example, charging the battery 5, the same AC current as in the example shown in FIG. 8 is input to the battery 5, and the frequency characteristic of the impedance of the battery 5 is measured for each of the SOC values as the measured value. In another example, the same superimposed current as in the example shown in FIG. 9 is input to the battery 5, and the frequency characteristic of the impedance of the battery 5 is measured for each of the SOC values as the measurement target while charging the battery 5. The frequency characteristic measurement unit 12 writes, in the data storage unit 16, the measurement result of the frequency characteristic of the impedance of the battery 5 for each of the plurality of SOC values. At this time, each of the SOC values as the measurement target is stored in the data storage unit 16 in association with the measurement result of the frequency characteristic of the impedance obtained for the SOC value.

The resistance calculation unit 13 calculates the resistance component of the impedance of the battery 5 based on the measurement result of the frequency characteristic of the impedance of the battery 5, that is, the measurement result of the impedance of the battery 5 at each of the plurality of frequencies. The resistance component of the impedance of the battery 5 is calculated for each of the plurality of SOC values for which the frequency characteristic of the impedance is measured. The resistance calculation unit 13 calculates, as the resistance components of the impedance of the battery 5, the charge transfer resistance Rc1 of the first electrode and the charge transfer resistance Rc2 of the second electrode for each of the plurality of SOC values for which the frequency characteristic of the impedance is measured. At this time, information concerning the vertex frequency F1 of the charge transfer impedance of the first electrode is stored in the data storage unit 16. The information concerning the vertex frequency F1 indicates, for example, one of a value such as a representative value for the vertex frequency F1 and an expression for deriving the vertex frequency F1 using the SOC of the battery 5. The resistance calculation unit 13 acquires the value of the vertex frequency F1 to be used to calculate the charge transfer resistances Rc1 and Rc2 for each of the plurality of SOC values as the measurement target of the frequency characteristic of the impedance by reading out the information concerning the vertex frequency F1 from the data storage unit 16.

In an example, an relational expression representing the relationship between the SOC of the battery 5 and the vertex frequency F1 and the like are stored in the data storage unit 16. The resistance calculation unit 13 calculates the vertex frequency F1 for each of the plurality of SOC values as the measurement target of the frequency characteristic of the impedance by, for example, substituting the SOC value into the above expression. Then, for each of the plurality of SOC values as the measurement target of the frequency characteristic, the charge transfer resistances Rc1 and Rc2 and the like are calculated using the value of the vertex frequency F1 calculated by the relational expression.

Furthermore, as described above, the vertex frequency F1 of the charge transfer impedance of the first electrode remains unchanged or almost unchanged even if the SOC of the battery 5 changes. Therefore, in another example, the representative value (fixed value) of the vertex frequency F1 is stored in the data storage unit 16. Then, for each of the plurality of SOC values as the measurement target of the frequency characteristic, the charge transfer resistances Rc1 and Rc2 and the like are calculated using the representative value as the value of the vertex frequency F1.

Note that the value such as the representative value of the vertex frequency F1, the relational expression representing the relationship between the SOC of the battery 5 and the vertex frequency F1, and the like, which are stored in the data storage unit 16, can be acquired from experiment data and the like in an experiment using a half cell including only the first electrode (a corresponding one of the positive electrode and the negative electrode). As the half cell, a three-pole cell using the first electrode for the working electrode and metal lithium for the reference electrode and the counter electrode, or a bipolar cell using the first electrode for the working electrode and metal lithium for the counter electrode can be used, but the half cell is not limited to them. Unlike the battery 5 as the diagnosis target, the information concerning the vertex frequency F1 is acquired using the half cell, and then, the frequency characteristic of the impedance is measured in regard to the battery 5 as the diagnosis target in the above-described way. Note that, similar to the battery 5, the frequency characteristic of the impedance can also be measured in regard to the half cell. Then, by analyzing data obtained by measuring the frequency characteristic of the impedance of the half cell, it is possible to acquire the vertex frequency F1 of the first electrode.

The data storage unit 16 stores an equivalent circuit model including information concerning the equivalent circuit of the battery 5. In the equivalent circuit of the equivalent circuit model, a plurality of electric characteristic parameters (circuit constants) corresponding to the impedance components of the battery 5 are set. The electric characteristic parameters set in the equivalent circuit include the above-described charge transfer resistance Rci (i=1, 2), and also include the above-described capacitance Ci and Debye experience parameter ai as the electric characteristic parameters of the CPE Qi serving as a circuit element. In the equivalent circuit, one or more of a resistance other than the charge transfer resistance Rci, a capacitance other than the capacitance Ci, an inductance, an impedance other than the charge transfer impedance, a parameter other than the Debye experience parameter ai, and the like may be set as an electric characteristic parameter.

Furthermore, the equivalent circuit model stored in the data storage unit 16 includes data representing the relationship between each of the vertex frequencies F1 and F2 and the electric characteristic parameters of the equivalent circuit, and data representing the relationship between the electric characteristic parameters of the equivalent circuit and the impedance of the battery 5. The data representing the relationship between each of the vertex frequencies F1 and F2 and the electric characteristic parameters of the equivalent circuit indicates an expression for calculating the vertex frequency F1 from the electric characteristic parameters corresponding to the impedance components of the charge transfer impedance of the first electrode, and an expression for calculating the vertex frequency F2 from the electric characteristic parameters corresponding to the impedance components of the charge transfer impedance of the second electrode, thereby indicating, for example, the relationship given by equation (2) above. The data representing the relationship between the electric characteristic parameters and the impedance of the battery 5 indicates an expression for calculating each of the real component and the imaginary component of the impedance from the electric characteristic parameters (circuit constants). In this case, in the expression, each of the real component and the imaginary component of the impedance of the battery 5 is calculated using the electric characteristic parameters, the frequency, and the like.

As will be described below, the resistance calculation unit 13 calculates the charge transfer resistances Rc1 and Rc2 using the equivalent circuit model for each of the plurality of SOC values for which the frequency characteristic of the impedance is measured. That is, in calculation of the charge transfer resistance Rci for each of the plurality of SOC values, the resistance calculation unit 13 performs fitting calculation using the equivalent circuit model including the equivalent circuit and the measurement result of the impedance of the battery 5 at each of a plurality of frequencies. At this time, the fitting calculation is performed using the electric characteristic parameters of the equivalent circuit as variables, thereby calculating the electric characteristic parameters as the variables. Furthermore, in the fitting calculation, for example, the values of the electric characteristic parameters as the variables are decided such that the difference between the calculation result of the impedance using the expression included in the equivalent circuit model and the measurement result of the impedance becomes as small as possible at each of the frequencies at which the impedance is measured. In the fitting calculation, a value acquired as the vertex frequency F1 based on the above-described information concerning the vertex frequency F1 is substituted, thereby performing calculation. In the fitting calculation, a constraint condition such as an equation for fixing a value to the above-described substituted value is preferably imposed on the vertex frequency F1.

By performing the fitting calculation, as described above, the electric characteristic parameters corresponding to the impedance components of the charge transfer impedance of each of the first electrode and the second electrode are calculated. This calculates the charge transfer resistance Rci of each of the first electrode and the second electrode, and calculates the capacitance Ci and the Debye experience parameter ai. The resistance calculation unit 13 calculates the above-described vertex frequency F2 of the second electrode for each of the plurality of SOC values for which the frequency characteristic of the impedance of the battery 5 is measured. The vertex frequency F2 is calculated by substituting the calculated charge transfer resistance Rc2, capacitance C2, and Debye experience parameter α2 into equation (2) above. Note that the equivalent circuit of the battery and the like are described in reference literature 1. Furthermore, the method of calculating the electric characteristic parameters (circuit constants) of the equivalent circuit by performing the fitting calculation using the measurement result in regard to the frequency characteristic of the impedance of the battery and the equivalent circuit model of the battery, and the like are also described in reference literature 1.

FIG. 11 is a circuit diagram schematically showing an example of the equivalent circuit of the battery used for the fitting calculation according to the first embodiment. In the equivalent circuit in the example shown in FIG. 11, resistances Ro1, Ro2, the resistances Rc1 and Rc2, a resistance Rc3, the capacitances C1 and C2, a capacitance C3, an inductance L1, impedances Zw1 and Zw2, the Debye experience parameters α1 and α2, and a Debye experience parameter α3 are set as the electric characteristic parameters corresponding to the impedance components of the battery 5. Here, the resistances Rol and Ro2 correspond to resistance components serving as ohmic resistances, the inductance L1 corresponds to the inductance component of the battery 5, and the impedances Zw1 and Zw2 correspond to impedance components serving as Warburg impedances. Furthermore, the resistance Rc3 corresponds to the coat resistance of a coat formed on the positive electrode or the negative electrode by a reaction or the like, and the resistance Rc3, the capacitance C3, and the Debye experience parameter α3 correspond to impedances derived from the coat including the coat resistance. The capacitance C3 and the Debye experience parameter α3 are the electric characteristic parameters of a CPE Q3.

In addition, in the equivalent circuit in the example shown in FIG. 11, the resistance (charge transfer resistance) Rc1, the capacitance C1, and the Debye experience parameter α1 are set as the electric characteristic parameters corresponding to the impedance components of the charge transfer impedance of the first electrode, as described above. The capacitance C1 and the Debye experience parameter α1 are the electric characteristic parameters of a CPE Ql. Furthermore, in the equivalent circuit in the example shown in FIG. 11, the resistance (charge transfer resistance) Rc2, the capacitance C2, and the Debye experience parameter α2 are set as the electric characteristic parameters corresponding to the impedance components of the charge transfer impedance of the second electrode, as described above. The capacitance C2 and the Debye experience parameter α2 are the electric characteristic parameters of a CPE Q2. When the electric characteristic parameters of the equivalent circuit in the example shown in FIG. 11 are calculated by the fitting calculation in the above-described way, the resistance Rc1 is calculated as the charge transfer resistance of the first electrode, and the resistance Rc2 is calculated as the charge transfer resistance of the second electrode. Then, the vertex frequency F2 of the charge transfer impedance of the second electrode is calculated using the calculation results of the resistance Rc2, the capacitance C2, and the Debye experience parameter α2 in the above described way.

The resistance calculation unit 13 calculates the charge transfer resistance Rc2 of the second electrode for each of the plurality of SOC values for which the frequency characteristic of the impedance of the battery 5 is measured, thereby acquiring the relationship between the charge transfer resistance Rc2 and the SOC of the battery 5. The relationship between the charge transfer resistance Rc2 and the SOC of the battery 5 is represented by a curve or the like on, for example, a graph with an abscissa representing the SOC of the battery 5 and an ordinate representing the charge transfer resistance Rc2. The curve or the like representing the relationship between the charge transfer resistance Rc2 and the SOC of the battery 5 is acquired by plotting a point representing the charge transfer resistance Rc2 for each of the plurality of SOC values on the above-described graph and performing the fitting calculation using the plotted point. In an example, in the fitting calculation, a function such as a quadratic function or cubic function representing the relationship between the SOC of the battery 5 and the charge transfer resistance Rc2 is used as a model formula for deriving the charge transfer resistance Rc2. In another example, in the fitting calculation, interpolation such as spline interpolation is performed.

The resistance calculation unit 13 calculates the vertex frequency F2 of the charge transfer impedance of the second electrode for each of the plurality of SOC values for which the frequency characteristic of the impedance of the battery 5 is measured, thereby acquiring the relationship between the vertex frequency F2 and the SOC of the battery 5. The relationship between the vertex frequency F2 and the SOC of the battery 5 is represented by a curve or the like on, for example, a graph with an abscissa representing the SOC of the battery 5 and an ordinate representing the vertex frequency F2. The curve or the like representing the relationship between the vertex frequency F2 and the SOC of the battery 5 is acquired by plotting a point representing the vertex frequency F2 for each of the plurality of SOC values on the above-described graph and performing the fitting calculation using the plotted point. The fitting calculation is performed in the same manner as that of the fitting calculation in deriving the curve representing the relationship between the charge transfer resistance Rc2 and the SOC of the battery 5. Note that the resistance calculation unit 13 need only acquire the relationship between the SOC of the battery 5 and at least one of the charge transfer resistance Rc2 and the vertex frequency F2. The resistance calculation unit 13 writes, in the data storage unit 16, the acquisition result of the relationship between the SOC of the battery 5 and at least one of the charge transfer resistance Rc2 and the vertex frequency F2.

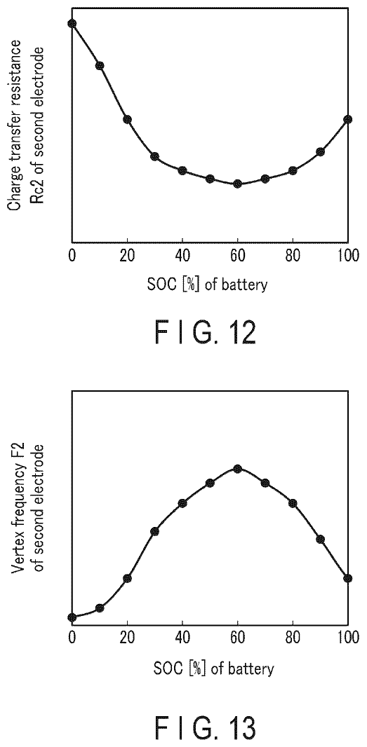

Based on the calculation result of the relationship between the SOC of the battery 5 and at least one of the charge transfer resistance Rc2 and the vertex frequency F2, the resistance calculation unit 13 specifies the SOC value of the battery 5 with which the vertex frequency F2 of the second electrode is maximum. The SOC value of the battery 5 with which the vertex frequency F2 is maximum corresponds to the SOC value of the battery 5 with which the charge transfer resistance Rc2 of the second electrode is minimum. FIG. 12 is a graph showing an example of the relationship between the charge transfer resistance of the second electrode and the SOC of the battery, which is acquired in the first embodiment. FIG. 13 is a graph showing the relationship between the vertex frequency of the charge transfer impedance of the second electrode and the SOC of the battery in a case where the relationship in the example shown in FIG. 12 is acquired. In FIGS. 12 and 13, the abscissa represents the SOC of the battery 5 in percentage. In FIG. 12, the ordinate represents the charge transfer resistance Rc2 of the second electrode. In FIG. 13, the ordinate represents the vertex frequency F2 of the second electrode.

In the example shown in FIGS. 12 and 13, in a case where the SOC value falls within the range of 0 (inclusive) to 1 (inclusive), the frequency characteristic of the impedance of the battery 5 is measured at an interval of 0.1 (10%) in SOC conversion of the battery 5. Then, for each of the plurality of SOC values for which the frequency characteristic of the impedance is measured, the charge transfer resistance Rc2 and the vertex frequency F2 of the second electrode are calculated in the above-described way. For each of the plurality of SOC values for which the frequency characteristic of the impedance is measured, the calculation result of the charge transfer resistance Rc2 is represented by a black point in FIG. 12 and the calculation result of the vertex frequency F2 is represented by a black point in FIG. 13. By performing the fitting calculation using the calculation result of the charge transfer resistance Rc2 for each of the plurality of SOC values, a curve shown in FIG. 12 is acquired as the relationship between the charge transfer resistance Rc2 and the SOC of the battery 5. Similarly, by performing the fitting calculation using the calculation result of the vertex frequency F2 for each of the plurality of SOC values, a curve shown in FIG. 13 is acquired as the relationship between the vertex frequency F2 and the SOC of the battery 5. As shown in FIG. 12 or the like, the relationship between the charge transfer resistance Rc2 of the second electrode and the SOC of the battery 5 has a convex shape to the lower side of the charge transfer resistance Rc2. As shown in FIG. 13 or the like, the relationship between the vertex frequency F2 of the charge transfer impedance of the second electrode and the SOC of the battery 5 has a convex shape to the higher side (upper side) of the vertex frequency F2. In the example shown in FIGS. 12 and 13, the resistance calculation unit 13 specifies the SOC=60% (0.6) as the SOC value of the battery 5 with which the vertex frequency F2 is maximum, that is, the SOC value of the battery 5 with which the charge transfer resistance Rc2 of the second electrode is minimum. The resistance calculation unit 13 writes, in the data storage unit 16, the SOC value specified as the SOC value of the battery 5 with which the vertex frequency F2 of the second electrode is maximum.

The electrode electric potential calculation unit 15 acquires the relationship in real time between the SOC of the battery 5 and at least one of the charging state (stoichiometry) and the electric potential of each of the electrodes (the first electrode and the second electrode) based on the relationship between the SOC of the battery 5 and at least one of the charge transfer resistance Rc2 and the vertex frequency F2. In an example, information indicating the relationship between the stoichiometry of the second electrode and at least one of the charge transfer resistance Rc2 and the vertex frequency F2 is stored in the data storage unit 16, and for example, at least one of the relationships shown in FIGS. 2 and 5 is included in the data stored in the data storage unit 16. The electrode electric potential calculation unit 15 acquires the relationship in real time between the stoichiometry (charging state) of the second electrode and the SOC of the battery 5 based on the acquisition result of the relationship between the SOC of the battery 5 and at least one of the charge transfer resistance Rc2 and the vertex frequency F2 and the relationship between the stoichiometry of the second electrode and at least one of the charge transfer resistance Rc2 and the vertex frequency F2. At this time, the corresponding value of the stoichiometry of the second electrode is calculated for each of the plurality of SOC values for which the frequency characteristic of the impedance is measured, thereby acquiring the relationship between the stoichiometry (charging state) of the second electrode and the SOC of the battery 5.

In another example, information indicating the relationship between the electric potential of the second electrode and at least one of the charge transfer resistance Rc2 and the vertex frequency F2 is stored in the data storage unit 16. The electrode electric potential calculation unit 15 acquires the relationship in real time between the electric potential of the second electrode and the SOC of the battery 5 based on the acquisition result of the relationship between the SOC of the battery 5 and at least one of the charge transfer resistance Rc2 and the vertex frequency F2 and the relationship between the electric potential of the second electrode and at least one of the charge transfer resistance Rc2 and the vertex frequency F2. At this time, the corresponding value of the electric potential of the second electrode is calculated for each of the plurality of SOC values for which the frequency characteristic of the impedance is measured, thereby acquiring the relationship between the electric potential of the second electrode and the SOC of the battery 5. Information representing the above-described predetermined relationship between the electric potential and stoichiometry (charging state) of the second electrode is stored in the data storage unit 16. Note that the charge transfer resistance Rc2 and the vertex frequency F2 have values corresponding to the charging state (stoichiometry) of the second electrode, that is, the electric potential of the second electrode.

Based on the acquisition result of the relationship in real time between the SOC of the battery 5 and one of the stoichiometry and electric potential of the second electrode and the above-described predetermined relationship between the electric potential and stoichiometry of the second electrode, the electrode electric potential calculation unit 15 acquires the relationship in real time between the SOC of the battery 5 and the other of the electric potential and stoichiometry of the second electrode. In this case, the corresponding value of the stoichiometry of the second electrode and the corresponding value of the electric potential of the second electrode are calculated for each of the plurality of SOC values for which the frequency characteristic of the impedance is measured, thereby acquiring the relationship between the SOC of the battery 5 and each of the stoichiometry and electric potential of the second electrode. Note that the electrode electric potential calculation unit 15 acquires the relationship in real time between the SOC of the battery 5 and at least one of the stoichiometry and the electric potential of the second electrode.

As described above, when the relationship between the stoichiometry of the second electrode and the SOC of the battery 5 is acquired, the value of the stoichiometry of the second electrode corresponding to each of the plurality of SOC values for which the frequency characteristic of the impedance is measured is calculated. For example, the value of the stoichiometry of the second electrode corresponding to a state in which the SOC of the battery 5 is 0 (a state of the lower limit voltage Vmin of the battery 5) and the value of the stoichiometry of the second electrode corresponding to a state in which the SOC of the battery 5 is 1 (a state of the upper limit voltage Vmax of the battery 5) are calculated. The electrode electric potential calculation unit 15 calculates, as a stoichiometry range usable in real time in regard to the second electrode, a range between the value of the stoichiometry of the second electrode corresponding to the state of SOC=0 (0%) and the value of the stoichiometry of the second electrode corresponding to the state of SOC=1 (100%).

Similarly, when the relationship between the electric potential of the second electrode and the SOC of the battery 5 is acquired, the value of the electric potential of the second electrode corresponding to each of the plurality of SOC values for which the frequency characteristic of the impedance is measured is calculated.

For example, the value of the electric potential of the second electrode corresponding to the state in which the SOC of the battery 5 is 0 (the state of the lower limit voltage Vmin of the battery 5) and the value of the electric potential of the second electrode corresponding to the state in which the SOC of the battery 5 is 1 (the state of the upper limit voltage Vmax of the battery 5) are calculated. The electrode electric potential calculation unit 15 calculates, as an electric potential range usable in real time in regard to the second electrode, a range between the value of the electric potential of the second electrode corresponding to the state of SOC=0 (0%) and the value of the electric potential of the second electrode corresponding to the state of SOC=1 (100%).

Furthermore, the electrode electric potential calculation unit 15 acquires the relationship in real time between the electric potential of the first electrode and the SOC of the battery 5 based on the acquisition result of the relationship in real time between the electric potential of the second electrode and the SOC of the battery 5. At this time, calculation is performed using the measurement result of the voltage of the battery 5 for each of the plurality of SOC values for which the frequency characteristic of the impedance of the battery 5 is measured. Then, for each of the plurality of SOC values for which the frequency characteristic of the impedance is measured, the corresponding value of the electric potential of the first electrode is calculated based on the measurement result of the voltage of the battery 5 and the calculation result of the electric potential of the second electrode. Note that in a case where each of a plurality of unit batteries provided in a battery module or the like is the battery 5 as the diagnosis target, the value of the electric potential of the first electrode corresponding to each of the plurality of SOC values for which the frequency characteristic of the impedance is measured is calculated using the average value of the voltages of the plurality of unit batteries as the measurement result of the voltage of the battery 5.

As described above, when the relationship between the electric potential of the first electrode and the SOC of the battery 5 is acquired, for example, the value of the electric potential of the first electrode corresponding to the state in which the SOC of the battery 5 is 0 (the state of the lower limit voltage Vmin of the battery 5) and the value of the electric potential of the first electrode corresponding to the state in which the SOC of the battery 5 is 1 (the state of the upper limit voltage Vmax of the battery 5) are calculated. The electrode electric potential calculation unit 15 calculates, as an electric potential range usable in real time in regard to the first electrode, a range between the value of the electric potential of the first electrode corresponding to the state of SOC=0 (0%) and the value of the electric potential of the first electrode corresponding to the state of SOC=1 (100%).

Information representing the above-described predetermined relationship between the electric potential and stoichiometry (charging state) of the first electrode is stored in the data storage unit 16. Based on the acquisition result of the relationship in real time between the electric potential of the first electrode and the SOC of the battery 5 and the above-described predetermined relationship between the electric potential and stoichiometry of the first electrode, the electrode electric potential calculation unit 15 acquires the relationship in real time between the stoichiometry of the first electrode the SOC of the battery 5. At this time, the corresponding value of the stoichiometry of the first electrode is calculated for each of the plurality of SOC values for which the frequency characteristic of the impedance is measured, thereby acquiring the relationship between the stoichiometry (charging state) of the first electrode and the SOC of the battery 5.

As described above, when the relationship between the stoichiometry of the first electrode and the SOC of the battery 5 is acquired, the value of the stoichiometry of the first electrode corresponding to each of the plurality of SOC values for which the frequency characteristic of the impedance is measured is calculated. For example, the value of the stoichiometry of the first electrode corresponding to the state in which the SOC of the battery 5 is 0 (the state of the lower limit voltage Vmin of the battery 5) and the value of the stoichiometry of the first electrode corresponding to the state in which the SOC of the battery 5 is 1 (the state of the upper limit voltage Vmax of the battery 5) are calculated. The electrode electric potential calculation unit 15 calculates, as a stoichiometry range usable in real time in regard to the first electrode, a range between the value of the stoichiometry of the first electrode corresponding to the state of SOC=0 (0%) and the value of the stoichiometry of the first electrode corresponding to the state of SOC=1 (100%).

The electrode electric potential calculation unit writes, in the data storage unit 16, the calculation results and the acquisition results obtained by the 15 above-described calculation and the like. The diagnosis apparatus 3 diagnoses degradation of the battery 5 and the like based on the calculation results and the acquisition results obtained by the calculation operations in the resistance calculation unit 13, the electrode electric potential calculation unit 15, and the like. The diagnosis result concerning degradation of the battery 5 and the like may be stored in the data storage unit 16.

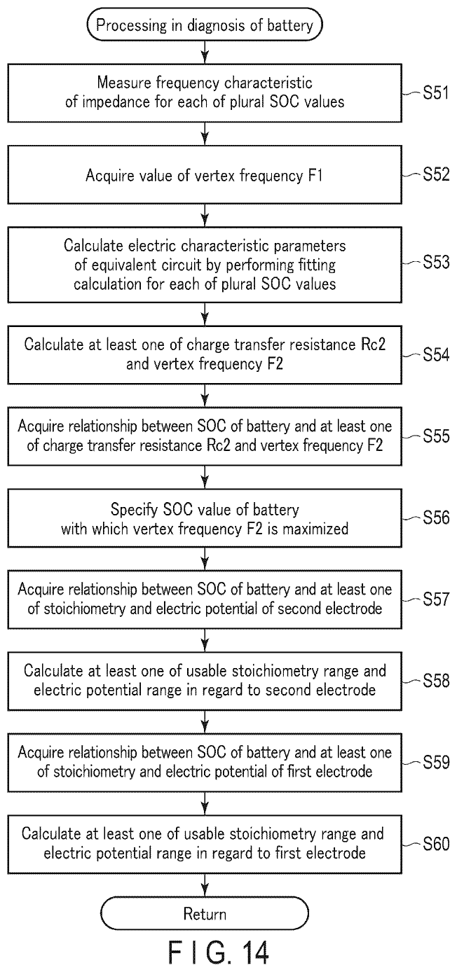

FIG. 14 is a flowchart schematically illustrating an example of processing in the diagnosis of the battery, which is performed by the diagnosis apparatus according to the first embodiment. When the processing shown in FIG. 14 is started, the frequency characteristic measurement unit 12 measures, for each of a plurality of SOC values, the frequency characteristic of the impedance of the battery 5 in the above-described way (step S51). At this time, an AC current or the above-described superimposed current is input to the battery 5, and the frequency characteristic of the impedance of the battery 5 is measured for each of the plurality of SOC values as the measurement target. The resistance calculation unit 13 acquires, as a value to be used for calculation, the value of the vertex frequency F1 of the charge transfer impedance of the first electrode from the information and the like stored in the data storage unit 16 (step S52). Then, the resistance calculation unit 13 calculates the electric characteristic parameters of the equivalent circuit by performing the fitting calculation using the equivalent circuit model and the measurement result of the frequency characteristic of the impedance of the battery 5 for each of the plurality of SOC values for which the frequency characteristic of the impedance is measured, in the above-described way (step S53). At this time, the fitting calculation is performed using the electric characteristic parameters of the equivalent circuit as variables and using the value of the vertex frequency F1 acquired in step S52.

After that, the resistance calculation unit 13 calculates at least one of the charge transfer resistance Rc2 of the second electrode and the vertex frequency F2 of the charge transfer impedance of the second electrode based on the calculation results of the electric characteristic parameters of the equivalent circuit for each of the plurality of SOC values for which the frequency characteristic of the impedance is measured (step S54). Then, the resistance calculation unit 13 acquires the relationship in real time between the SOC of the battery 5 and at least one of the charge transfer resistance Rc2 and the vertex frequency F2, in the above-described way, from the calculation result of at least one of the charge transfer resistance Rc2 and the vertex frequency F2 for each of the plurality of SOC values (step S55). The resistance calculation unit 13 specifies, from the relationship between the SOC of the battery 5 and at least one of the charge transfer resistance Rc2 and the vertex frequency F2, the SOC value of the battery 5 with which the vertex frequency F2 of the second electrode is maximum, that is, the SOC value of the battery 5 with which the charge transfer resistance Rc2 of the second electrode is minimum (step S56).

After that, the electrode electric potential calculation unit 15 acquires the relationship between the SOC of the battery 5 and at least one of the stoichiometry (charging state) and the electric potential of the second electrode, in the above-described way, based on the acquisition result of the relationship between the SOC of the battery 5 and at least one of the charge transfer resistance Rc2 and the vertex frequency F2 (step S57).

Then, the electrode electric potential calculation unit 15 calculates at least one of a usable stoichiometry range and a usable electric potential range in regard to the second electrode based on the relationship between the SOC of the battery 5 and at least one of the stoichiometry and the electric potential of the second electrode, and the like (step S58). Furthermore, based on the relationship between the SOC of the battery 5 and at least one of the stoichiometry and the electric potential of the second electrode, the measurement result of the voltage of the battery 5, and the like, the electrode electric potential calculation unit 15 acquires the relationship between the SOC of the battery 5 and at least one of the stoichiometry and the electric potential of the first electrode (step S59). The electrode electric potential calculation unit 15 calculates at least one of a usable stoichiometry range and a usable electric potential range in regard to the first electrode based on the relationship between the SOC of the battery 5 and at least one of the stoichiometry and the electric potential of the first electrode, and the like (step S60).

As described above, according to this embodiment, the battery 5 including the first electrode including the first electrode active material that performs a two-phase coexistence reaction and the second electrode including the second active material that performs a single-phase reaction and having a polarity opposite to that of the first electrode is the diagnosis target. Then, in the diagnosis of the battery 5, the relationship between the SOC of the battery 5 and at least one of the charge transfer resistance and the vertex frequency of the second electrode is acquired in the above-described way. When the relationship in real time between the SOC of the battery 5 and at least one of the charge transfer resistance and the vertex frequency of the second electrode is acquired, it is possible to appropriately estimate, in the above-described way, the relationship in real time between the SOC of the battery 5 and the stoichiometry (charging state) and electric potential of each of the first electrode and the second electrode using the acquired relationship.

When the relationship in real time between the SOC of the battery 5 and the stoichiometry (charging state) and the electric potential of each of the first electrode and the second electrode is appropriately estimated, the accuracy of the diagnosis of degradation of the battery 5 and the like is improved. Furthermore, when the relationship in real time between the SOC of the battery 5 and the stoichiometry (charging state) and the electric potential of each of the first electrode and the second electrode is appropriately estimated, it is possible to charge/discharge the battery 5 under the operation condition of the battery 5 based on the appropriately estimated relationship. This effectively prevents overcharging, overdischarging, and the like of each of the first electrode and the second electrode in the battery 5.

### Second Embodiment

Next, the second embodiment will be described as a modification of the first embodiment. In the second embodiment, for each of a first time such as the start of use of a battery 5 and a second time after the first time, a resistance calculation unit 13 acquires the relationship between the SOC of the battery 5 and at least one of a charge transfer resistance Rc2 and a vertex frequency F2 of a second electrode in the above-described way. Then, for each of the first time and the second time, the SOC value of the battery 5 with which the vertex frequency F2 of the second electrode is maximum, that is, the SOC value of the battery 5 with which the charge transfer resistance Rc2 of the second electrode is minimum is specified in the above-described way. In this embodiment, an electrode electric potential calculation unit 15 calculates a shift of the stoichiometry of the second electrode in the second time with respect to the stoichiometry of the second electrode in the first time, by comparing the specification result for the first time with that for the second time in regard to to the SOC value of the battery 5 with which the vertex frequency F2 of the second electrode is maximum.

Under the normal use condition, even if the battery 5 degrades, the relationship between the vertex frequency F2 of the second electrode and the stoichiometry of the second electrode remains unchanged or almost unchanged depending on the degree of degradation. Therefore, it is possible to calculate a shift of the stoichiometry of the second electrode in the second time with respect to the first time, by comparing the specification result for the first time with that for the second time in regard to the SOC value of the battery 5 with which the vertex frequency F2 of the second electrode is maximum.

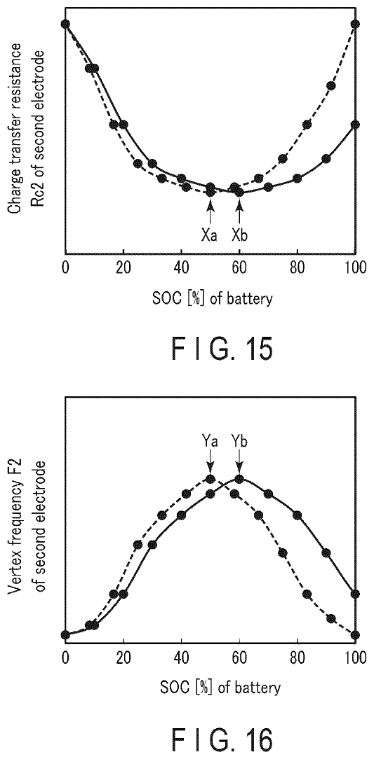

FIG. 15 is a graph showing an example of the relationship between the charge transfer resistance of the second electrode and the SOC of the battery in each of the first time and the second time after the first time, which is acquired in the second embodiment. FIG. 16 is a graph showing the relationship between the vertex frequency of the charge transfer impedance of the second electrode and the SOC of the battery in each of the first time and the second time, in a case where the relationship in the example shown in FIG. 15 is acquired. In FIGS. 15 and 16, the abscissa represents the SOC of the battery 5 in percentage. In FIG. 15, the ordinate represents the charge transfer resistance Rc2 of the second electrode. In FIG. 16, the ordinate represents the vertex frequency F2 of the second electrode. Furthermore, in FIGS. 15 and 16, a solid line indicates the relationship for the first time, and a broken line indicates the relationship for the second time.

In the example shown in FIGS. 15 and 16, the frequency characteristic of the impedance of the battery 5 is measured for each of a plurality of SOC values in each of the first time and the second time. In each of the first time and the second time, in a case where the SOC value falls within the range of 0 (inclusive) to 1 (inclusive), the frequency characteristic of the impedance of the battery 5 is measured at an interval of 0.1 (10%) in SOC conversion of the battery 5. Then, for each of the first time and the second time, the charge transfer resistance Rc2 and the vertex frequency F2 of the second electrode for each of the plurality of SOC values for which the frequency characteristic of the impedance is measured are calculated in the above-described way.

In the example shown in FIGS. 15 and 16, the charge transfer resistance Rc2 becomes minimum at a point Xb in the relationship between the charge transfer resistance Rc2 and the SOC of the battery 5 in the first time, and the vertex frequency F2 becomes maximum at a point Yb in the relationship between the vertex frequency F2 and the SOC of the battery 5 in the first time. Therefore, the resistance calculation unit 13 specifies the SOC=60% (0.6) as the SOC value of the battery 5 with which the vertex frequency F2 is maximum (the charge transfer resistance Rc2 is minimum) in the first time. Furthermore, in the example shown in FIGS. 15 and 16, the charge transfer resistance Rc2 becomes minimum at a point Xa in the relationship between the charge transfer resistance Rc2 and the SOC of the battery 5 in the second time, and the vertex frequency F2 becomes maximum at a point Ya in the relationship between the vertex frequency F2 and the SOC of the battery 5 in the second time. Therefore, the resistance calculation unit 13 specifies the SOC=50% (0.5) as the SOC value of the battery 5 with which the vertex frequency F2 is maximum (the charge transfer resistance Rc2 is minimum) in the second time.

In the example shown in FIGS. 15 and 16, the SOC value of the battery 5 with which the charge transfer resistance Rc2 is minimum, that is, the SOC value of the battery 5 with which the vertex frequency F2 is maximum is calculated to be 10% (0.1) lower in the second time than in the first time. Therefore, it is calculated by the electrode electric potential calculation unit 15 that when compared under the condition that the SOC values of the battery 5 are identical to each other, the stoichiometry of the second electrode in the second time is shifted by about 10% in SOC conversion of the battery 5 to the high electric potential side with respect to the stoichiometry of the second electrode in the first time. Therefore, in this embodiment, a shift of the stoichiometry of the second electrode with respect to a given past time point (the first time) is calculated by comparing data at the given past time point with data in real time (the second time) in regard to the relationship between the SOC of the battery 5 and at least one of the charge transfer resistance Rc2 and the vertex frequency F2 of the second electrode.

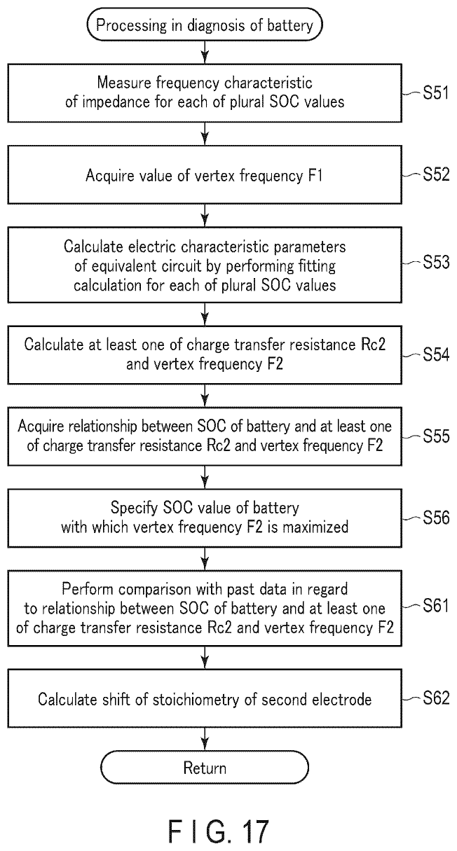

FIG. 17 is a flowchart schematically illustrating an example of processing in the diagnosis of the battery, which is performed by the diagnosis apparatus according to the second embodiment. The processing shown in FIG. 17 is performed at a time point at which past data concerning the relationship between the SOC of the battery 5 and at least one of the charge transfer resistance Rc2 and the vertex frequency F2 of the second electrode has already been acquired, for example, in the above-described second time. In the diagnosis processing shown in FIG. 17 as well, processes in steps S51 to S56 are sequentially performed, similar to the diagnosis processing shown in FIG. 14.

In step S56, after the resistance calculation unit 13 and the like specify the SOC value of the battery 5 with which the vertex frequency F2 of the second electrode is maximum in real time, the electrode electric potential calculation unit 15 compares the past data at, for example, the start of use of the battery 5 with real-time data in regard to the relationship between the SOC of the battery 5 and at least one of the charge transfer resistance Rc2 and the vertex frequency F2 of the second electrode (step S61). Then, the electrode electric potential calculation unit 15 calculates a shift of the stoichiometry of the second electrode in real time with respect to the given past time point such as the start of use of the battery 5 in the above-described way based on the comparison result between the past data and the real-time data (step S62).

Furthermore, in this embodiment, the electrode electric potential calculation unit 15 may acquire the relationship between the SOC of the battery 5 and at least one of the stoichiometry and the electric potential of the second electrode for each of the first time and the second time after the first time. In this case as well, similar to the first embodiment and the like, the relationship between the SOC of the battery 5 and at least one of the stoichiometry and the electric potential of the second electrode is acquired. Then, the electrode electric potential calculation unit 15 calculates a shift of the stoichiometry of the second electrode in the second time with respect to the stoichiometry of the second electrode in the first time based on the relationship between the SOC of the battery 5 and at least one of the stoichiometry and the electric potential of the second electrode in each of the first time and the second time. The shift of the stoichiometry of the second electrode is calculated by performing, for example, conversion into the SOC of the battery 5 in the above-described way. In the calculation of the shift of the stoichiometry of the second electrode, for example, the (past) data in the first time is compared with the (real-time) data in the second time in regard to the relationship between the SOC of the battery 5 and at least one of the stoichiometry and the electric potential of the second electrode.

In this embodiment, the electrode electric potential calculation unit 15 may acquire the relationship between the SOC of the battery 5 and at least one of the stoichiometry and the electric potential of a first electrode for each of the first time and the second time after the first time. In this case as well, the relationship between the SOC of the battery 5 and at least one of the stoichiometry and the electric potential of the first electrode is acquired, similar to the first embodiment and the like. Then, the electrode electric potential calculation unit 15 calculates a shift of the stoichiometry of the first electrode in the second time with respect to the stoichiometry of the first electrode in the first time based on the relationship between the SOC of the battery 5 and at least one of the stoichiometry and the electric potential of the first electrode in each of the first time and the second time. The shift of the stoichiometry of the first electrode is calculated by performing, for example, conversion into the SOC of the battery 5. In the calculation of the shift of the stoichiometry of the first electrode, for example, the (past) data in the first time is compared with the (real-time) data in the second time in regard to the relationship between the SOC of the battery 5 and at least one of the stoichiometry and the electric potential of the first electrode.

As described above, in this embodiment, a shift of the stoichiometry of each of the first electrode and the second electrode with respect to the given past time point such as the start of use of the battery 5 is calculated. When the shift of the stoichiometry of each of the electrodes is appropriately calculated, the accuracy of the diagnosis of degradation of the battery 5 and the like is further improved.

### Third Embodiment

Next, the third embodiment will be described as a modification of the above-described embodiment or the like. In the third embodiment, a measurement circuit 6 measures, as a parameter αssociated with a battery 5, a temperature T of the battery 5 in addition to the current and voltage of the battery 5. Measurement data measured by the measurement circuit 6 includes the measurement result of the temperature T of the battery 5 and a time change (time history) of the temperature T. In this embodiment, a frequency characteristic measurement unit 12 measures the frequency characteristic of the impedance of the battery 5 for each of SOC values as a measurement target, and also acquires the temperature T of the battery 5 at the time of measurement of the frequency characteristic. Therefore, the measurement result of the frequency characteristic of the impedance for each of the SOC values as the measurement target is stored in a data storage unit 16 in association with the temperature T of the battery 5 at the time of the measurement.

In this embodiment as well, a resistance calculation unit 13 calculates at least one of a charge transfer resistance Rc2 of a second electrode and a vertex frequency F2 of the charge transfer impedance of the second electrode, in the above-described way, for each of a plurality of SOC values for which the frequency characteristic of the impedance is measured. However, in this embodiment, for each of the plurality of SOC values for which the frequency characteristic is measured, the resistance calculation unit 13 corrects, based on the measurement result of the temperature T of the battery 5, the charge transfer resistance Rc2 and/or the vertex frequency F2 calculated by fitting calculation. In an example, the calculated vertex frequency F2 is corrected using equation (3) corresponding to the Arrhenius equation. In equation (3), a reference temperature T0, the measured temperature T, and a parameter Ea indicating the gradient of the vertex frequency F2 with respect to the temperature T are defined. The values of the reference temperature T0 and the parameter Ea and the like are stored in the data storage unit 16 and the like. In equation (3), a function F2(T) represents the vertex frequency F2 at the temperature T, and a frequency F2(T0) represents the value of the vertex frequency F2 at the reference temperature T0.

F2(T)=F2(T0)exp[Ea {(1/T0)−(1/T)}] (3)

The charge transfer resistance Rc2 is also corrected based on the temperature T, similar to the vertex frequency F2. Therefore, in this embodiment, the resistance calculation unit 13 calculates at least one of the charge transfer resistance Rc2 and the vertex frequency F2 of the second electrode based on the temperature T of the battery 5 in addition to the measurement result of the frequency characteristic of the impedance of the battery 5 for each of the plurality of SOC values of the battery 5. Then, the resistance calculation unit 13 acquires the relationship between the SOC of the battery 5 and at least one of the charge transfer resistance Rc2 and the vertex frequency F2 using the charge transfer resistance Rc2 and the vertex frequency F2 which have been corrected based on the temperature T. In this embodiment as well, the electrode electric potential calculation unit 15 executes, for example, acquisition of the relationship between the SOC of the battery 5 and at least one of the stoichiometry and the electric potential of each of a first electrode and the second electrode using the relationship between the SOC of the battery 5 and at least one of the charge transfer resistance Rc2 and the vertex frequency F2.

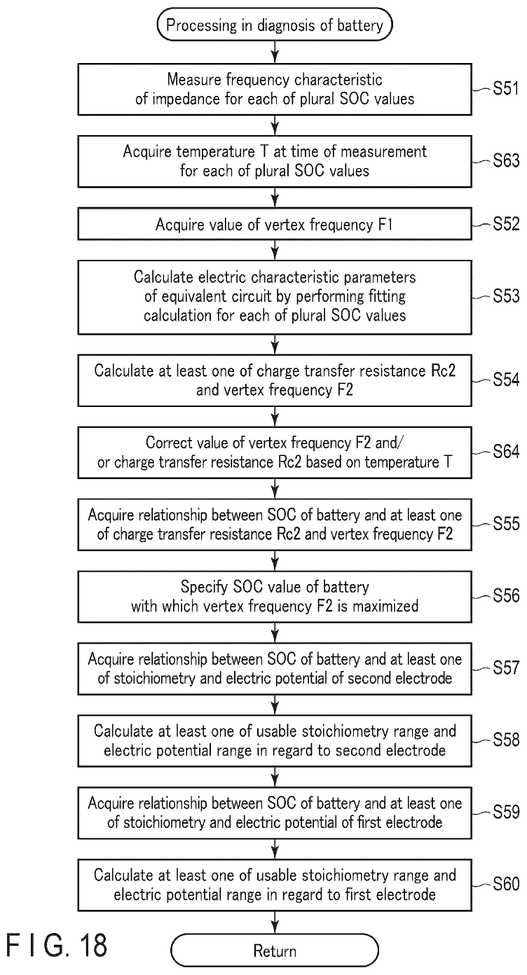

FIG. 18 is a flowchart schematically illustrating an example of processing in the diagnosis of the battery performed by a diagnosis apparatus according to the third embodiment. When the diagnosis processing shown in FIG. 18 is started, processing in step S51 is executed, similar to the diagnosis processing shown in FIG. 14 or the like. Then, after the frequency characteristic of the impedance of the battery 5 is measured for each of a plurality of SOC values in step S51, the resistance calculation unit 13 acquires the temperature T at the time of the measurement for each of the plurality of SOC values for which the frequency characteristic is measured (step S63). In the diagnosis processing shown in FIG. 18 as well, processes in steps S52 to S54 are sequentially executed, similar to the diagnosis processing shown in FIG. 14 or the like.

After at least one of the charge transfer resistance Rc2 and the vertex frequency F2 is calculated for each of the plurality of SOC values in step S54, the resistance calculation unit 13 corrects, for each of the plurality of SOC values for which the frequency characteristic is measured, based on the measurement result of the temperature T of the battery 5, the charge transfer resistance Rc2 and/or the vertex frequency F2 calculated by fitting calculation (step S64). Then, the resistance calculation unit 13 acquires the relationship between the SOC of the battery 5 and at least one of the charge transfer resistance Rc2 and the vertex frequency F2 using the charge transfer resistance Rc2 and the vertex frequency F2 which have been corrected based on the temperature T (step S55). In the diagnosis processing shown in FIG. 18 as well, processes in steps S55 to S60 are sequentially executed, similar to the diagnosis processing shown in FIG. 14 or the like.

In this embodiment, for each of the plurality of SOC values of the battery 5, at least one of the charge transfer resistance Rc2 and the vertex frequency F2 of the second electrode is calculated based on the temperature T of the battery 5 in addition to the measurement result of the frequency characteristic of the impedance of the battery 5. Therefore, the accuracy of estimation of the charge transfer resistance Rc2 and the vertex frequency F2 of the second electrode is improved. This more appropriately estimates the relationship between the SOC of the battery 5 and at least one of the stoichiometry and the electric potential of each of the first electrode and the second electrode, and the like, thereby further improving the accuracy of the diagnosis of degradation of the battery 5 and the like.

Note that in an example, the resistance calculation unit 13 calculates the value of the vertex frequency F1 to be used for fitting calculation based on the measurement result of the temperature T for each of the plurality of SOC values for which the frequency characteristic of the impedance is measured. In this case, data representing the relationship between the temperature T and the vertex frequency F1 is stored in the data storage unit 16. In an example, an equation similar to equation (3) above and corresponding to the Arrhenius equation is stored as an equation representing the relationship between the temperature T and the vertex frequency F1. Then, the resistance calculation unit 13 corrects the value of the vertex frequency F1 based on the measurement result of the temperature T and the equation corresponding to the Arrhenius equation. In the fitting calculation, the value corrected based on the equation corresponding to the Arrhenius equation is substituted as the vertex frequency F1, thereby performing calculation.

In this example as well, similar to the example shown in FIG. 18 or the like, the resistance calculation unit 13 calculates at least one of the charge transfer resistance Rc2 and the vertex frequency F2 of the second electrode for each of the plurality of SOC values of the battery 5 based on the temperature T of the battery 5 in addition to the measurement result of the frequency characteristic of the impedance of the battery 5. Therefore, the same function and effect as in the embodiment including the example shown in FIG. 18 can be obtained.

### Fourth Embodiment

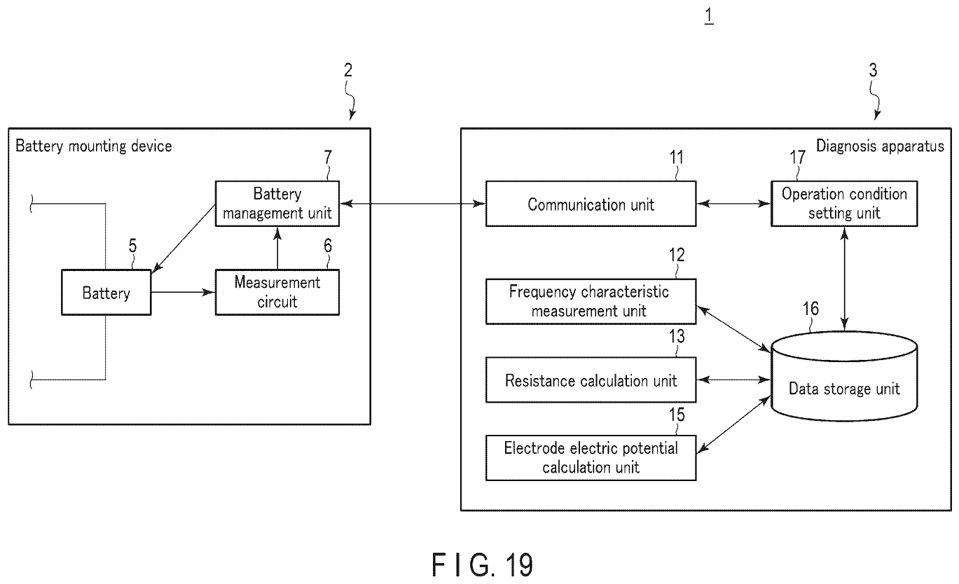

Next, the fourth embodiment will be described as a modification of the above-described embodiment or the like. FIG. 19 is a schematic block diagram showing a management system of a battery according to the fourth embodiment. As shown in FIG. 19, in this embodiment, a diagnosis apparatus 3 of a management system 1 includes an operation condition setting unit 17 in addition to a communication unit 11, a frequency characteristic measurement unit 12, a resistance calculation unit 13, an electrode electric potential calculation unit 15, and a data storage unit 16. In a case where the diagnosis apparatus 3 is a server or the like, the operation condition setting unit 17 executes some of processes performed by the processor of the diagnosis apparatus 3 and the like. In a case where the diagnosis apparatus 3 is a cloud server or the like, the operation condition setting unit 17 executes some of processes performed by a virtual processor and the like.

The operation condition setting unit 17 sets (updates) a condition concerning the operation of the battery 5 such as charging and discharging of the battery 5 based on the diagnosis result of the battery 5 including one of the relationship between the SOC of a battery 5 and at least one of a charge transfer resistance Rc2 and a vertex frequency F2 of a second electrode, a shift of the stoichiometry of the second electrode with respect to that at the start of use, and the like. Then, the operation condition setting unit 17 transmits, to a battery management unit 7, via the communication unit 11, a control command based on the newly set condition concerning the operation. The battery management unit 7 controls the operation of the battery 5 including charging and discharging based on the control command from the operation condition setting unit 17. This controls charging and discharging of the battery 5 and the like based on the diagnosis result of the battery 5.

In an example, a condition concerning a current flowing to the battery 5 such as the C rate is set based on the shift amount of the stoichiometry of the second electrode with respect to the stoichiometry at the start of use. In this case, as the shift amount of the stoichiometry of the second electrode in real time with respect to the stoichiometry at the start of use is larger, the upper limit of the current flowing to the battery 5 is set lower. In another example, the voltage range of the battery 5 at the time of the operation (charging and discharging) of the battery 5 is set based on the shift amount of the stoichiometry of the second electrode with respect to the stoichiometry at the start of use. In this case, as the shift amount of the stoichiometry of the second electrode in real time with respect to the stoichiometry at the start of use is larger, the voltage range of the battery 5 at the time of the operation of the battery 5 is set narrower. Note that the condition concerning the operation of the battery 5 may be set based on the acquisition result of the relationship between the SOC of the battery 5 and the electric potential and stoichiometry of a first electrode, and the acquisition result of the relationship between the SOC of the battery 5 and the electric potential and stoichiometry of the second electrode and the like.

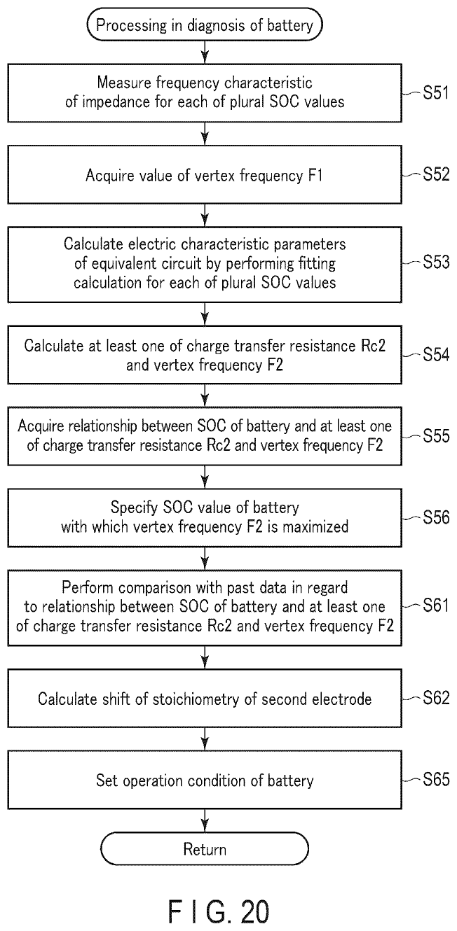

FIG. 20 is a flowchart schematically illustrating an example of processing in the diagnosis of the battery, which is performed by the diagnosis apparatus according to the fourth embodiment. When the diagnosis processing shown in FIG. 20 is started, processes in steps S51 to S56, S61, and S62 are sequentially executed, similar to the diagnosis processing shown in FIG. 17 or the like. After the shift of the stoichiometry of the second electrode in real time with respect to the stoichiometry at a given past time point such as the start of use of the battery 5 is calculated in step S62, the operation condition setting unit 17 sets the operation condition of the battery 5 in the above-described way (step S65). At this time, the condition concerning the operation of the battery 5 is set based on the relationship between the SOC of the battery 5 and at least one of the charge transfer resistance Rc2 and the vertex frequency F2 of the second electrode, the shift of the stoichiometry of the second electrode with respect to the stoichiometry at the start of use, and the like.

In this embodiment, charging and discharging of the battery 5 are controlled based on the relationship between the SOC of the battery 5 and at least one of the charge transfer resistance Rc2 and the vertex frequency F2 of the second electrode, the shift of the stoichiometry of the second electrode with respect to the stoichiometry at the start of use, and the like. Therefore, the operation of the battery 5 is appropriately controlled in accordance with the real-time state of the battery 5.

In at least one of the above-described embodiments and examples, a secondary battery including a first electrode including a first electrode active material that performs a two-phase coexistence reaction and a second electrode including a second active material that performs a single-phase reaction and having a polarity opposite to that of the first electrode is diagnosed. Then, at least one of the charge transfer resistance and the vertex frequency of the second electrode is calculated based on the measurement result of the impedance of the secondary battery for each of a plurality of SOC values of the secondary battery, thereby acquiring the relationship between the SOC of the secondary battery and at least one of the charge transfer resistance and the vertex frequency of the second electrode. This can provide a diagnosis method of a secondary battery, a charging and discharging control method, a diagnosis apparatus, a management system, and a diagnosis program that can appropriately estimate the relationship in real time between the charging state of each electrode and the SOC of the secondary battery.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A diagnosis method of a secondary battery which includes a first electrode including a first electrode active material that performs a two-phase coexistence reaction, and a second electrode including a second active material that performs a single-phase reaction and having a polarity opposite to a polarity of the first electrode, the method comprising:
acquiring a relationship between an SOC of the secondary battery and at least one of a charge transfer resistance and a vertex frequency of the second electrode by calculating at least one of the charge transfer resistance and the vertex frequency of the second electrode based on a measurement result of an impedance of the secondary battery for each of a plurality of SOC values of the secondary battery.

2. The diagnosis method according to claim 1, further comprising specifying, based on the relationship between the SOC of the secondary battery and at least one of the charge transfer resistance and the vertex frequency of the second electrode, an SOC value of the secondary battery with which the vertex frequency of the second electrode is maximum.

3. The diagnosis method according to claim 2, further comprising:
specifying, for each of a first time and a second time after the first time, the SOC value of the secondary battery with which the vertex frequency of the second electrode is maximum; and
calculating a shift of a stoichiometry of the second electrode in the second time with respect to the stoichiometry of the second electrode in the first time by performing conversion into the SOC of the secondary battery by comparing a specification result for the first time with a specification result for the second time in regard to the SOC value of the secondary battery with which the vertex frequency of the second electrode is maximum.

4. The diagnosis method according to claim 1, further comprising acquiring a relationship between the SOC of the secondary battery and at least one of a stoichiometry and an electric potential of the second electrode based on the relationship between the SOC of the secondary battery and at least one of the charge transfer resistance and the vertex frequency of the second electrode.

5. The diagnosis method according to claim 4, further comprising:
acquiring, for each of the first time and the second time after the first time, the relationship between the SOC of the secondary battery and at least one of the stoichiometry and the electric potential of the second electrode; and
calculating the shift of the stoichiometry of the second electrode in the second time with respect to the stoichiometry of the second electrode in the first time by performing conversion into the SOC of the secondary battery based on the relationship between the SOC of the secondary battery and at least one of the stoichiometry and the electric potential of the second electrode for each of the first time and the second time.

6. The diagnosis method according to claim 4, further comprising calculating at least one of a usable stoichiometry range and a usable electric potential range in regard to the second electrode based on the relationship between the SOC of the secondary battery and at least one of the stoichiometry and the electric potential of the second electrode.

7. The diagnosis method according to claim 4, further comprising:
acquiring a relationship between the SOC of the secondary battery and at least one of a stoichiometry and an electric potential of the first electrode based on the relationship between the SOC of the secondary battery and at least one of the stoichiometry and the electric potential of the second electrode; and
calculating at least one of a usable stoichiometry range and a usable electric potential range in regard to the first electrode based on the relationship between the SOC of the secondary battery and at least one of the stoichiometry and the electric potential of the first electrode.

8. The diagnosis method according to claim 1, wherein in the acquiring the relationship between the SOC of the secondary battery and at least one of the charge transfer resistance and the vertex frequency of the second electrode,
at least one of the charge transfer resistance and the vertex frequency of the second electrode is calculated based on a temperature of the secondary battery in addition to the measurement result of the impedance of the secondary battery for each of the plurality of SOC values of the secondary battery.

9. The diagnosis method according to claim 1, wherein in the acquiring the relationship between the SOC of the secondary battery and at least one of the charge transfer resistance and the vertex frequency of the second electrode,
by performing fitting calculation using an equivalent circuit set with a plurality of electric characteristic parameters including an electric characteristic parameter corresponding to a charge transfer impedance of the first electrode and an electric characteristic parameter corresponding to a charge transfer impedance of the second electrode, and the measurement result of the impedance of the secondary battery, the electric characteristic parameters of the equivalent circuit are calculated for each of the plurality of SOC values of the secondary battery, and
at least one of the charge transfer resistance and the vertex frequency of the second electrode is calculated based on a calculation result of the electric characteristic parameter corresponding to a charge transfer impedance of the second electrode for each of the plurality of SOC values of the secondary battery.

10. The diagnosis method according to claim 1, further comprising measuring the impedance of the secondary battery for each of the plurality of SOC values of the secondary battery by inputting, to the secondary battery, a superimposed current generated by superimposing a current waveform of an AC current on a DC current.

11. A charging and discharging control method of a secondary battery, comprising:
diagnosing the secondary battery by the diagnosis method according to claim 1; and
controlling charging and discharging of the secondary battery based on a diagnosis result of the secondary battery including the relationship between the SOC of the secondary battery and at least one of the charge transfer resistance and the vertex frequency of the second electrode.

12. A diagnosis apparatus of a secondary battery which includes a first electrode including a first electrode active material that performs a two-phase coexistence reaction and a second electrode including a second active material that performs a single-phase reaction and having a polarity opposite to a polarity of the first electrode, the apparatus comprising:
a processor configured to acquire a relationship between an SOC of the secondary battery and at least one of a charge transfer resistance and a vertex frequency of the second electrode by calculating at least one of the charge transfer resistance and the vertex frequency of the second electrode based on a measurement result of an impedance of the secondary battery for each of a plurality of SOC values of the secondary battery.

13. A management system of a secondary battery, comprising:
the diagnosis apparatus according to claim 12; and
the secondary battery diagnosed by the diagnosis apparatus.

14. The management system according to claim 13, wherein in the secondary battery, the first electrode is one of a negative electrode including lithium titanate as the first electrode active material and a positive electrode including lithium iron phosphate as the first electrode active material.

15. A non-transitory storage medium storing a diagnosis program of a secondary battery which includes a first electrode including a first electrode active material that performs a two-phase coexistence reaction and a second electrode including a second active material that performs a single-phase reaction and having a polarity opposite to a polarity of the first electrode, the diagnosis program causing a computer to:
acquire a relationship between an SOC of the secondary battery and at least one of a charge transfer resistance and a vertex frequency of the second electrode by calculating at least one of the charge transfer resistance and the vertex frequency of the second electrode based on a measurement result of an impedance of the secondary battery for each of a plurality of SOC values of the secondary battery.
